(19) United States
(12) Patent Application Publication
(10) Pub. No.: US 2024/0304241 A1
(43) Pub. Date: Sep. 12, 2024

(54) MEMORY BIT CELLS WITH THREE-DIMENSIONAL CROSS FIELD EFFECT TRANSISTORS

(71) Applicant: Advanced Micro Devices, Inc., Santa Clara, CA (US)

(72) Inventors: Richard T. Schultz, Fort Collins, CO (US); Kerrie Vercant Underhill, Boxborough, MA (US)

(21) Appl. No.: 18/181,054

(22) Filed: Mar. 9, 2023

(51) Int. Cl. G11C 11/419; H01L 23/528; H01L 29/06; H01L 29/417; H01L 29/423; H01L 29/786; H10B 10/00

(52) U.S. Cl. CPC G11C 11/419; H01L 23/5283; H01L 29/0673; H01L 29/41733; H01L 29/42392; H01L 29/78696; H10B 10/125

(57) ABSTRACT

An apparatus and method for efficiently creating layout for memory bit cells are described. In various implementations, a memory bit cell uses pairs of transistors that are vertically stacked gate all around (GAA) transistors with gate terminals forming a T-shape with respect to one another and a single gate contact that overlaps only one active layer of the two active layers of the pair. Transistors of such a pair of field effect transistors (FETs) are referred to as TFETs. With respect to one another, the active layers of TFETs use opposite doping polarities and conduct current in an orthogonal direction. A non-overlapping distance between top and bottom active layers of a pair of TFETs is at least a width of a drain/source contact. The orthogonal current flow of the top and bottom active layers simplifies local connections that reduces the resistance and capacitance of the signal routes.

### BACKGROUND

### Description of the Relevant Art

As both semiconductor manufacturing processes advance and on-die geometric dimensions reduce, semiconductor chips provide more functionality and performance while consuming less space. While many advances have been made, design issues still arise with modern techniques in processing and integrated circuit design that limit potential benefits. For example, capacitive coupling, electro migration, short channel effects such as at least leakage currents, and processing yield are some issues which affect the placement of devices and the routing of signals across an entire die of a semiconductor chip. These issues have the potential to delay completion of the design and affect the time to market.

In order to shorten the design cycle for semiconductor chips, manual full-custom designs are replaced with automation where possible. In some cases, a standard cell layout is created manually. In other cases, the rules used by the place-and-route tool are adjusted to automate the cell creation. However, the automated process at times does not satisfy each of the rules directed at performance, power consumption, signal integrity, process yield, both local and external signal routing including internal cross coupled connections, pin access, and so on. Therefore, designers manually create these cells to achieve better results for the multiple characteristics or rewrite the rules for the place-and-route tool. However, many times, the layout tools and rules are setup for planer devices, rather than for the relatively recent non-planar devices. One example of these cells is the memory bit cell of a random-access memory.

Generally speaking, a variety of semiconductor chips include at least one processing unit coupled to a memory. The processing unit sends memory access requests to the memory for fetching instructions, fetching data, and storing results of computations. Static random-access memory (SRAM) is commonly used as the memory. The SRAM includes an array of many memory bit cells and surrounding circuitry used for accessing values stored in the array. The die or the package can include other units or components in addition to the processing unit and the memory. The dimensions of the individual components have limits in order to place all of the components on a same die or a same package. For several types of memory, such as the SRAM, the dimensions are large enough that they interfere with the placement of other components. Consequently, the chip is rendered inoperable or requires a larger and more expensive package without significant redesign.

In view of the above, methods and systems for efficiently creating layout for memory bit cells are desired.

### BRIEF DESCRIPTION OF THE DRAWINGS

FIG. 1 is a generalized diagram of a cross-section view of a semiconductor device layout.

FIG. 2 is a generalized block diagram of a top view of a standard cell layout.

FIG. 3 is a generalized block diagram of a top view of a standard cell layout.

FIG. 4 is a generalized diagram of data storage circuitry of a memory bit cell.

FIG. 5 is a generalized block diagram of a top view of a standard cell layout.

FIG. 6 is a generalized block diagram of a top view of a standard cell layout.

FIG. 7 is a generalized block diagram of a top view of a standard cell layout.

FIG. 8 is a generalized block diagram of a top view of a standard cell layout.

FIG. 9 is a generalized block diagram of a top view of a standard cell layout.

FIG. 10 is a generalized block diagram of a top view of a standard cell layout.

FIG. 11 is a generalized block diagram of a top view of a standard cell layout.

FIG. 12 is a generalized block diagram of a top view of a standard cell layout.

FIG. 13 is a generalized diagram of a memory bank.

FIG. 14 is a generalized block diagram of a top view of a standard cell layout.

FIG. 15 is a generalized block diagram of a top view of a standard cell layout.

FIG. 16 is a generalized block diagram of a top view of a standard cell layout.

FIG. 17 is a generalized block diagram of a top view of a standard cell layout.

FIG. 18 is a generalized block diagram of a top view of a standard cell layout.

FIG. 19 is a generalized block diagram of a top view of a standard cell layout.

FIG. 20 is a generalized block diagram of a top view of a standard cell layout.

FIG. 21 is a generalized block diagram of a top view of a standard cell layout.

FIG. 22 is a generalized block diagram of a top view of a standard cell layout.

FIG. 23 is a generalized block diagram of a top view of a standard cell layout.

FIG. 24 is a generalized diagram of a method for efficiently creating layout for memory bit cells that utilize TFETs.

FIG. 25 is a generalized diagram of computing system with an integrated circuit that uses an array of memory bit cells that utilize TFETs.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Systems and methods for efficiently creating layout for memory bit cells are contemplated. In various implementations, one or more standard cells include a transistor pair with gate terminals forming a T-shape with respect to one another. As used herein, a “transistor” is also referred to as a “field effect transistor” (FET), a “semiconductor device” or a “device.” In some implementations, the pair of transistors are vertically stacked gate all around (GAA) transistors such as a top vertical GAA transistor (or GAA transistor) is formed vertically on top of a bottom GAA transistor with at least an isolating oxide layer in between the two GAA transistors.

In addition, the top GAA transistor of the transistor pair has one or more conducting channels (or channels) positioned orthogonal to the one or more conducting channels of the bottom GAA transistor. Therefore, the direction of current flow of the top GAA transistor through one or more top channels is orthogonal to the direction of current flow of the one or more bottom channels of the bottom GAA transistor. In some implementations, a channel includes a conducting lateral nanowire. In other implementations, the channel includes a conducting nanosheet. In such implementations, the current of a particular transistor flows through one or more channels, or in other words, the current of the particular transistor flows through one or more nanosheets.

The pair of the top and bottom GAA transistors (two vertically stacked transistors) also includes a single gate contact, which is used to connect a same input signal to the two gate terminals of the pair of vertically stacked transistors. This single gate contact overlaps only one active layer of two active layers (i.e., only one, not both) used to form the pair of vertically stacked transistors. For example, this single gate contact overlaps only one active layer of an n-type active layer of an n-type transistor and a p-type active layer of a p-type transistor that is formed either above or below the n-type transistor in a vertically stacked manner. As used herein, an “active layer” refers to a region of a semiconductor wafer where doped silicon is formed. For planar transistors (devices), the active layer defines the regions where the silicon substrate is doped with either p-type atoms (dopants) or n-type atoms (dopants). For non-planar transistors (devices), the active layer defines the regions of the three-dimensional structures above the silicon substrate that contain doped silicon such as where the channels are formed. The pair of vertically stacked transistors with gate terminals forming a T-shape with respect to one another and a single gate contact that overlaps only one active layer of two active layers used to form the pair of vertically stacked transistors is referred to as “TFETs.”

The top GAA transistor of the TFETs has a doping polarity of the top active layer that is an opposite polarity of the doping polarity of the bottom active layer of the bottom GAA transistor. In an implementation, the top GAA transistor includes a p-type active layer, whereas, the bottom GAA transistor includes an n-type active layer. In another implementation, the p-type and n-type polarities are reversed between the active layers of the top GAA transistor and the bottom GAA transistor. With the orthogonal orientation between the top GAA transistor and the bottom GAA transistor, both the top and bottom GAA transistors have the maximum drive current for their respective carriers based on their orientation. It is understood that a silicon wafer, an integrated circuit, and a semiconductor package using the silicon substrate layer can be rotated and flipped. Therefore, the materials and layers being described would be rotated and flipped, and the orientations and directions would have a different meaning. Therefore, the terms “top,” “bottom,” “horizontal,” “vertical,” “above,” and “below” can change as the layout is rotated or flipped.

In various implementations, the top active layer of the top GAA transistor of the two vertically stacked transistors does not overlap the bottom active layer of the bottom GAA transistor of the two vertically stacked transistors. A non-overlapping distance between the first (top) active layer and the second (bottom) active layer includes at least a width of a source or drain contact. The single gate contact, which is used to connect a same input signal to both gate terminals of the top and bottom GAA transistors, overlaps only one active layer of the top active layer and the bottom active layer. In an implementation, the single gate contact overlaps at least a portion of the bottom active layer. With respect to the location of the single gate contact, the gate terminals of the top and bottom GAA transistors form a T-shape. The placement of the single gate contact overlapping only one active layer of the top and bottom active layers simplifies semiconductor fabrication and improves fabrication yield when compared to placing the single gate contact in a manner that overlaps both the top and bottom active layers.

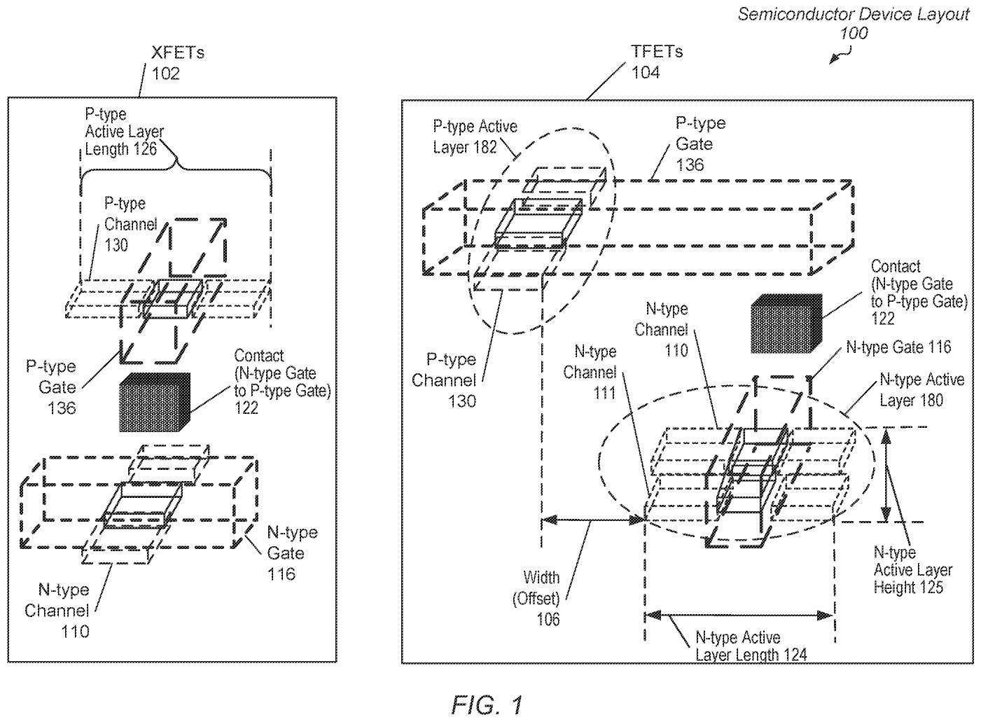

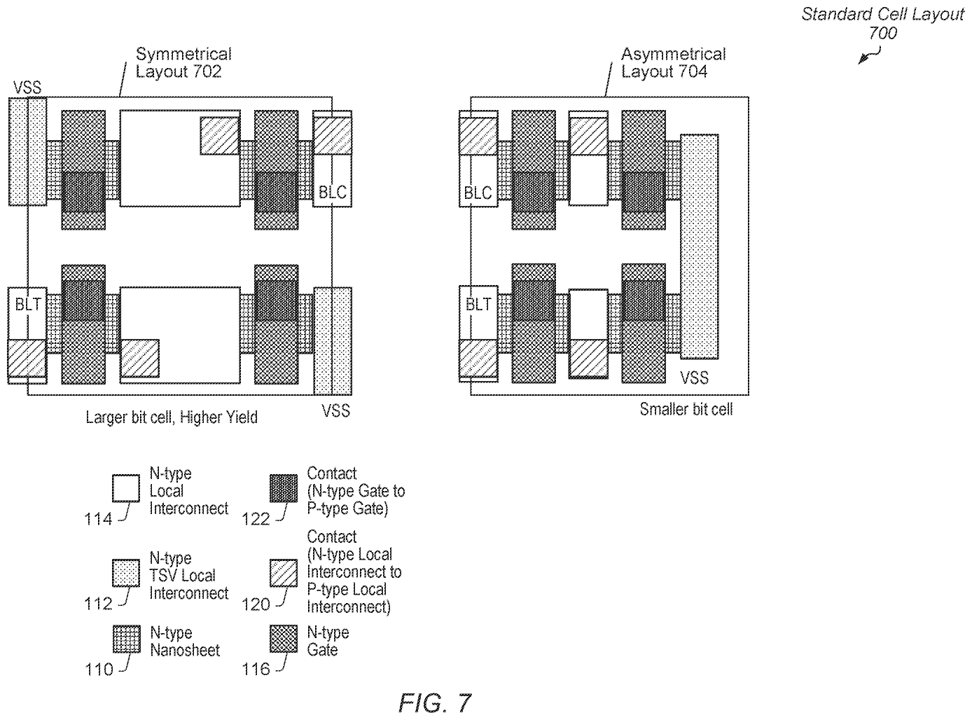

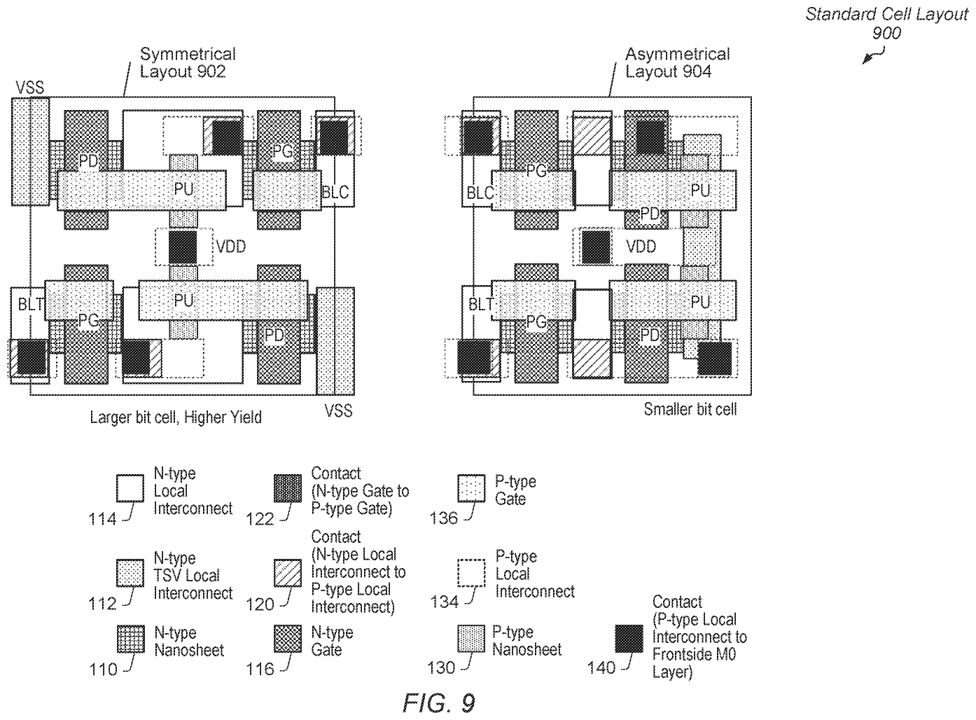

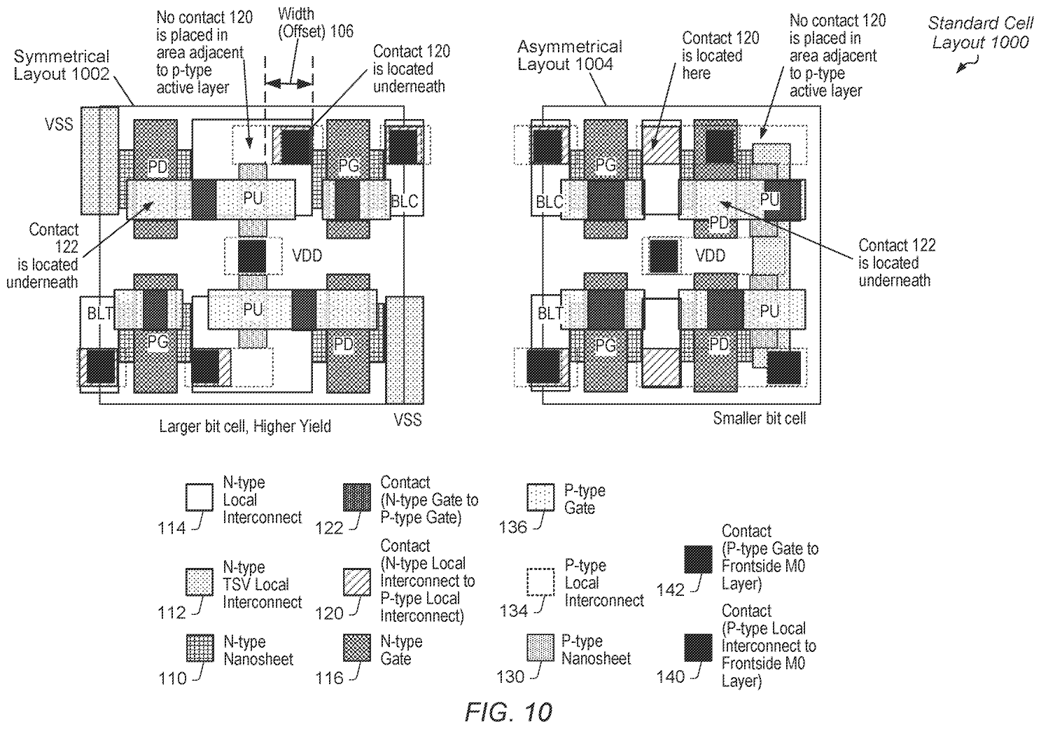

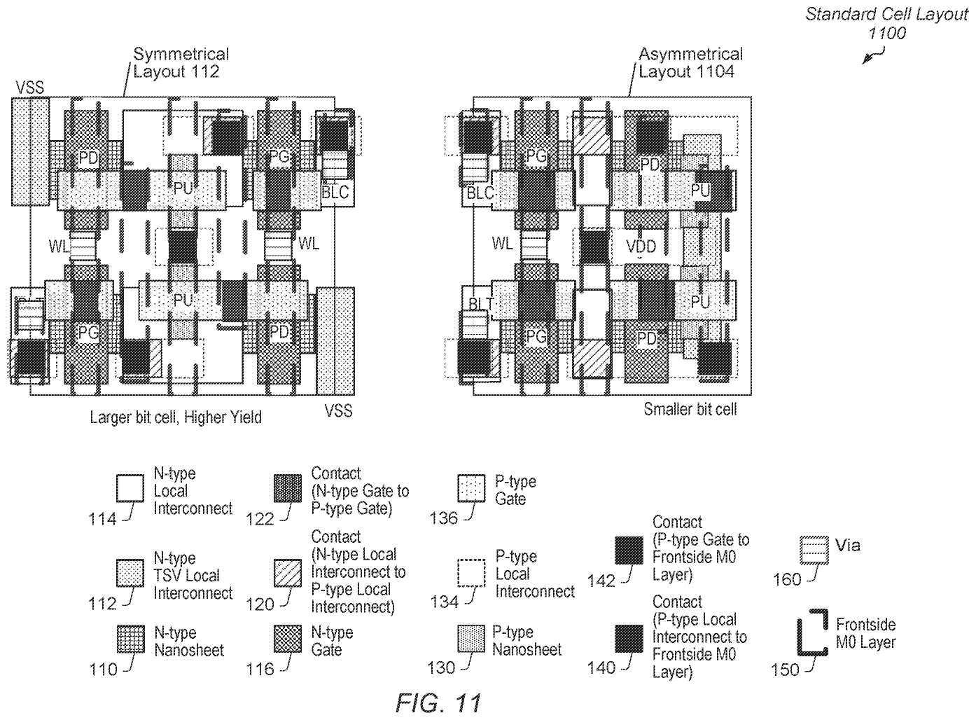

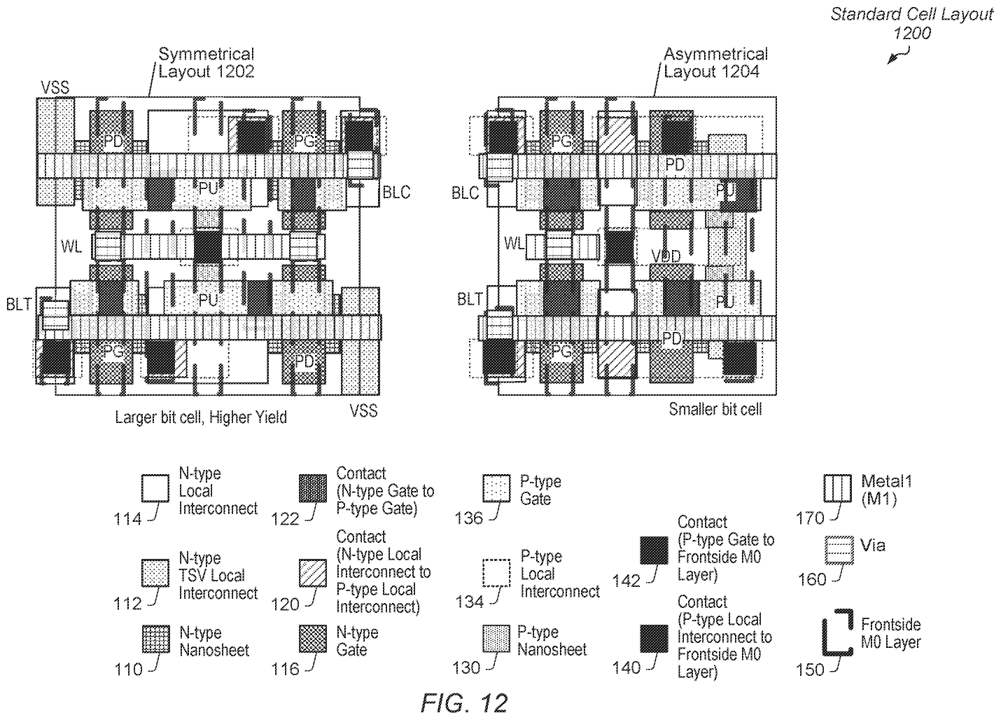

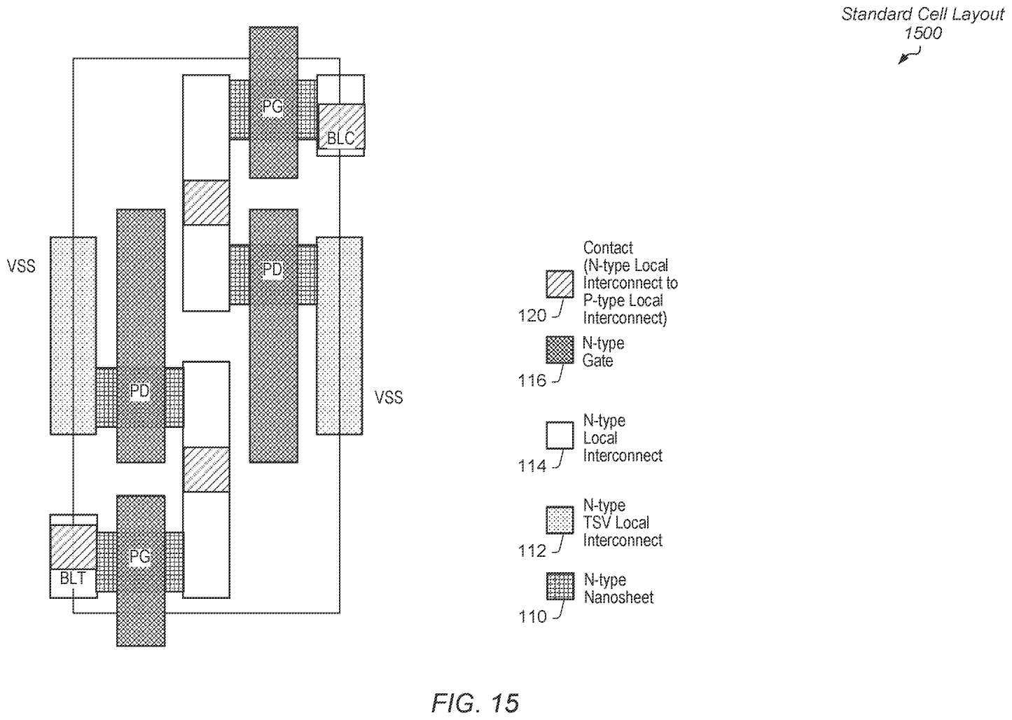

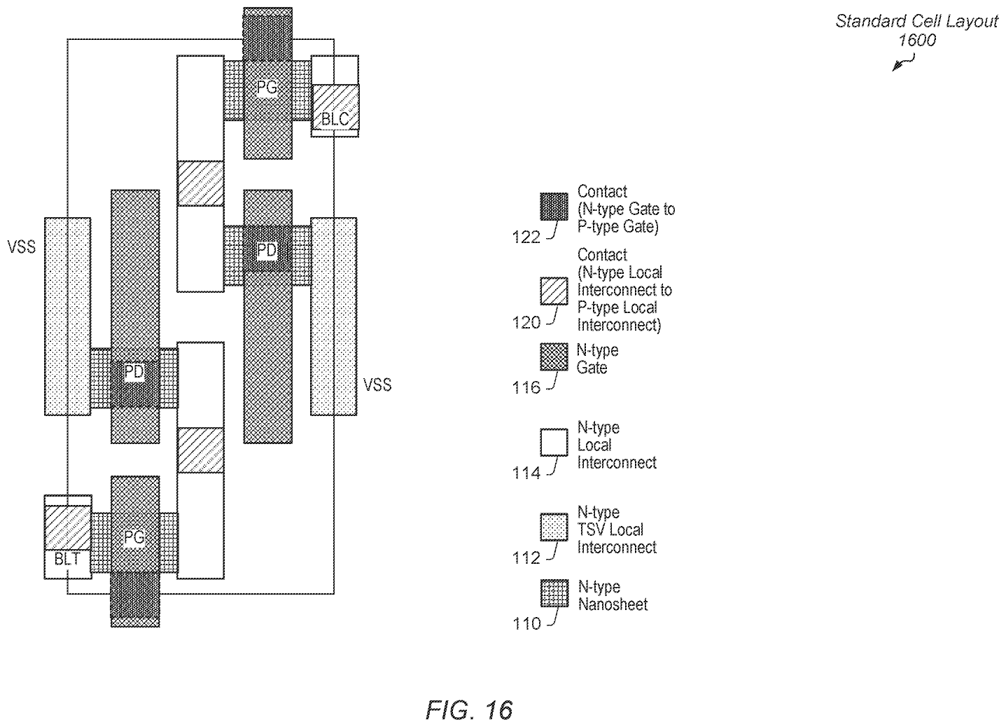

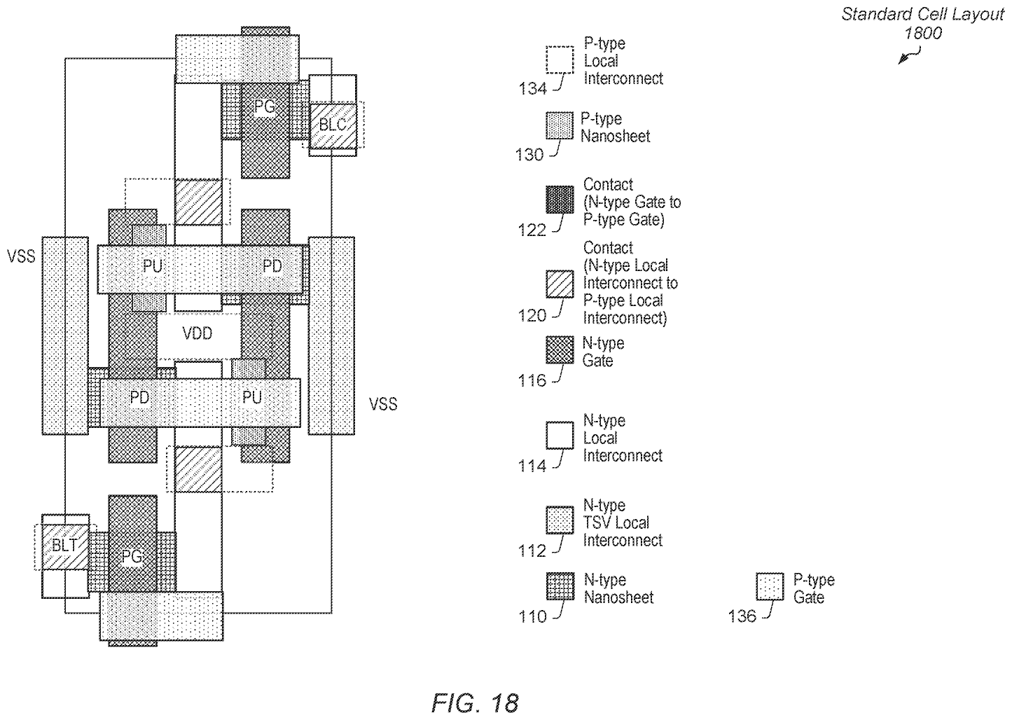

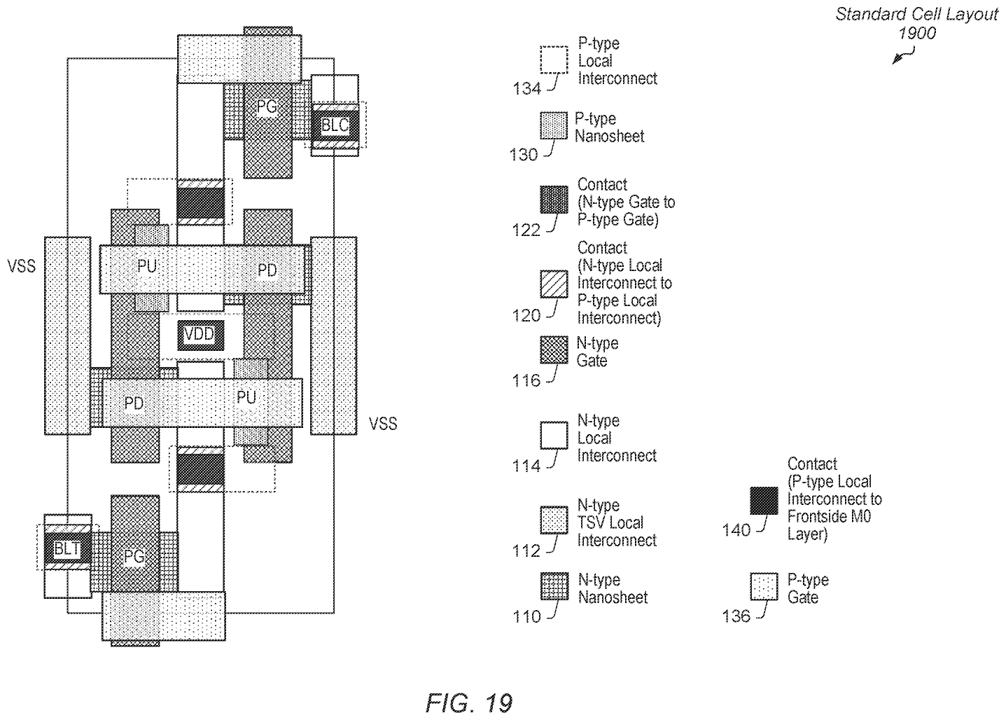

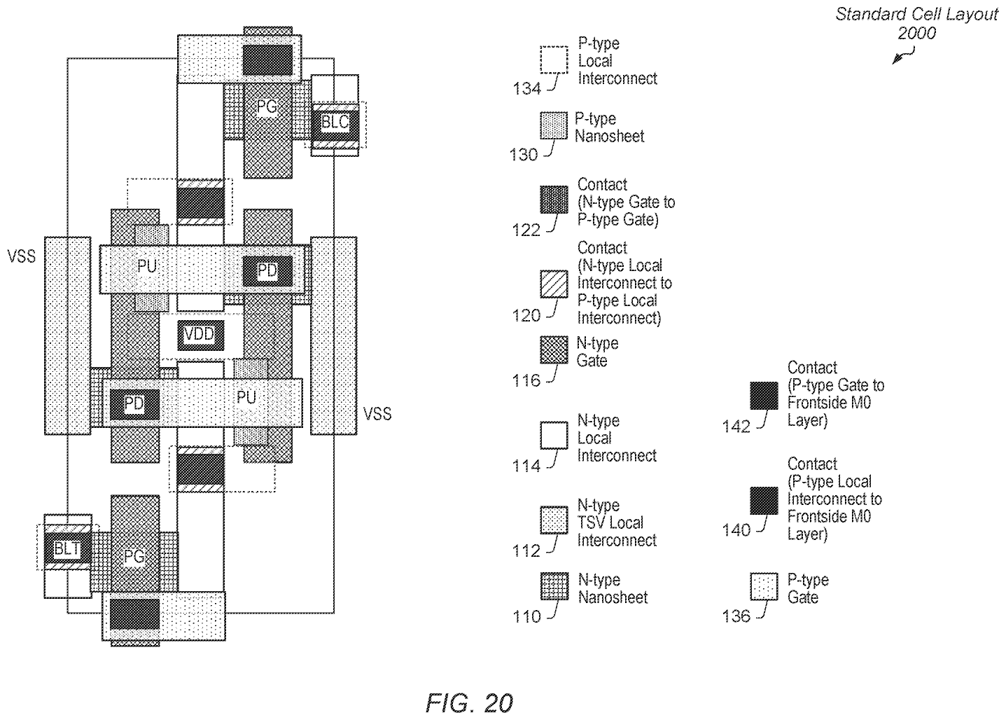

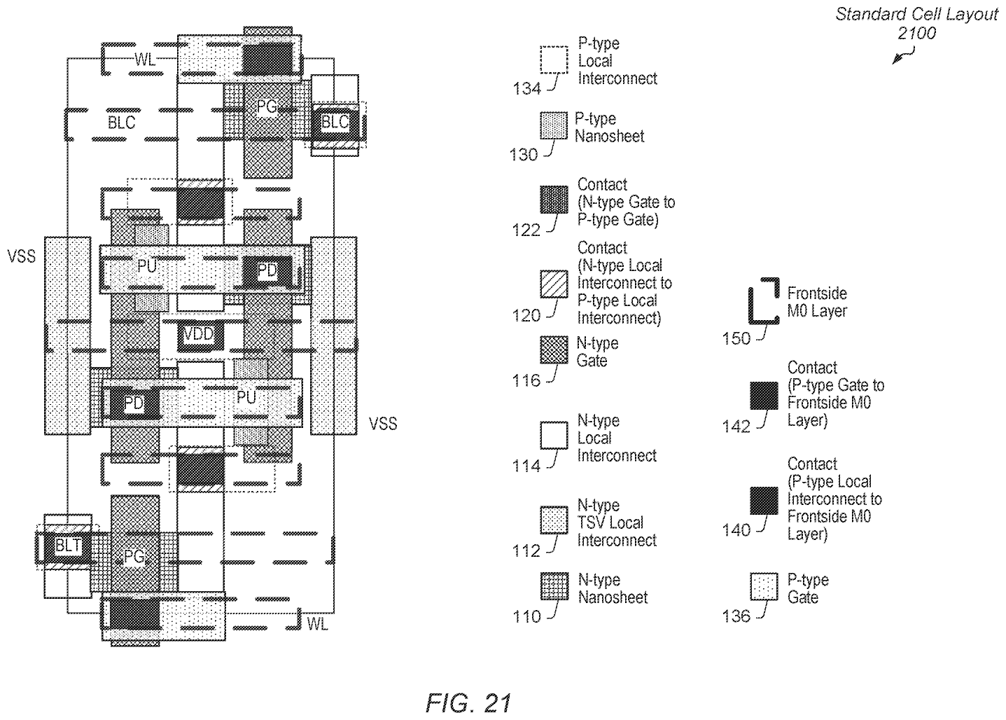

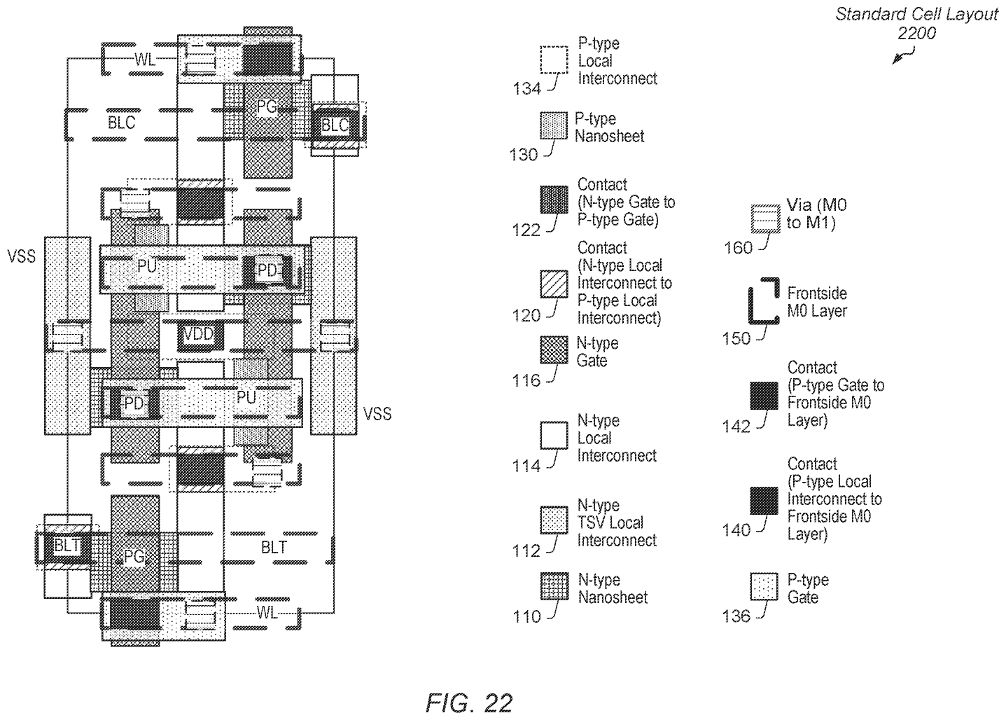

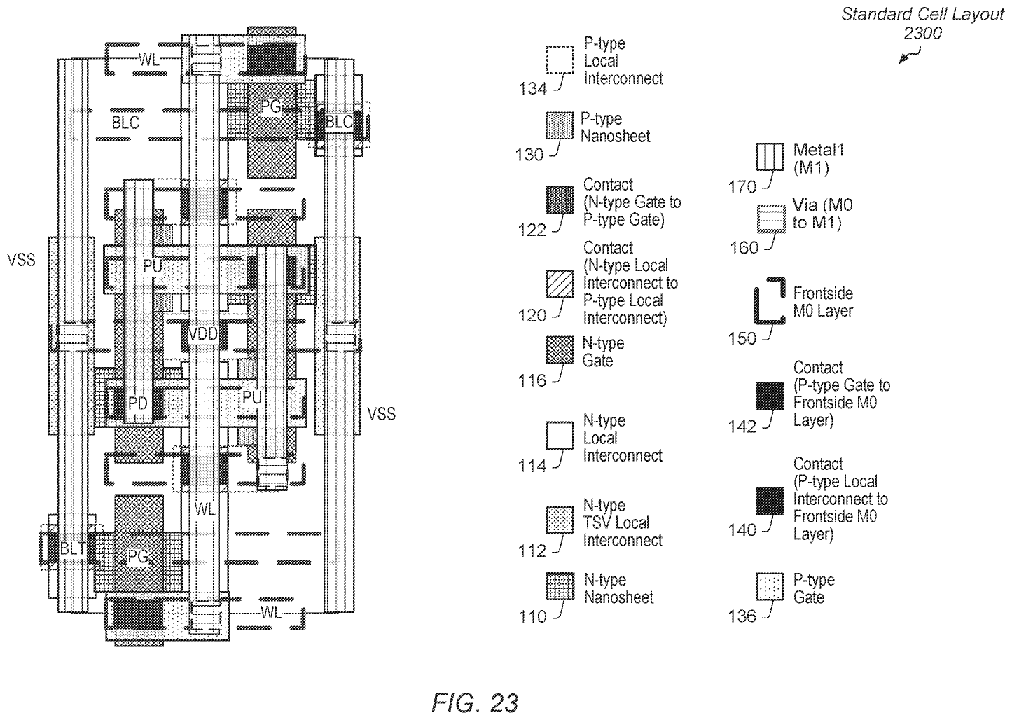

A memory array (or array) utilizes memory bit cells arranged as multiple rows and multiple columns. These memory bit cells use TFETs. In various implementations, the orthogonal current flow of the top and bottom active layers simplifies local connections for cross-coupled inverters that reduces the resistance and capacitance of the signal routes, and increases performance as a result. A first memory bit cell includes, between drain nodes of a p-type pullup transistor and an n-type pulldown transistor, a drain contract contacting an area of a local interconnect layer of the p-type pullup transistor. This area of the local interconnect layer is not physically adjacent to the p-type active layer of the p-type pullup transistor. Further details of an array using TFETs are provided in the below description of FIGS. 1-25.

Turning now to FIG. 1, a generalized block diagram of a cross-section view of semiconductor device layout 100 is shown that uses TFETs. The semiconductor materials of Cross field effect transistors (FETs) 102 are shown in the left diagram or box. Cross FETs are also referred to as “XFETs.” Therefore, the Cross FETs 102 are also referred to as XFETs 102. The semiconductor materials of TFETs 104 are shown in the right diagram or box. Three-dimensional (3-D) illustrations of the p-type and n-type Cross FETs 102 and TFETs 104 are shown. Each of the XFETs 102 and the TFETs 104 include a p-type device that is vertically stacked on an n-type device. The n-type device includes at least an n-type gate 116 formed all around an n-type channel 110. Similarly, a p-type gate 136 is formed all around a p-type channel 130. Therefore, the p-type channel 130 has a doping polarity that is an opposite polarity of the n-type channel 110 of the bottom n-type device.

Although a single n-type channel 110 and a single p-type channel 130 is shown for the Cross FETs 102, in other implementations, the semiconductor devices include another number of conducting channels (or channels). As an example, the TFETs 104 include the n-type channel 110 and the n-type channel 111. In some implementations, the channel includes one or more conducting lateral nanowires. In other implementations, the channel includes one or more conducting nanosheets. A nanosheet is a sheet of doped silicon, rather than a wire of doped silicon. In other words, the nanosheet is a wider conductive wire than a lateral nanowire. The nanosheet can also be considered as a Fin that is rotated and placed on its side vertically above the silicon substrate such that the nanosheet does not have physical contact with the silicon substrate. Rather, metal gate is formed between the nanosheet and the silicon substrate. This visualization, though, does not describe the actual fabrication steps for forming the nanosheet.

Compared to Fin FETs, the use of gate all around (GAA) nanowires or nanosheets provides lower threshold voltages, faster switching times, less leakage currents, and further reduction of short channel effects. Examples of short channel effects other than leakage current are latchup effects, drain-induced barrier lowering (DIBL), punchthrough, performance dependency on temperature, impact ionization, and parasitic capacitance to the silicon substrate. As described earlier, an “active layer” refers to a region of a semiconductor wafer where doped silicon is formed. For planar transistors (devices), the active layer defines the regions where the silicon substrate is doped with either p-type atoms (dopants) or n-type atoms (dopants). For non-planar transistors (devices), the active layer defines the regions of the three-dimensional structures above the silicon substrate that contain doped silicon such as where the channels are formed.

In the illustrated implementations, the XFETs 102 has an n-type active layer (not labeled) that includes the single n-type channel 110. In other implementations, the n-type active layer of the n-type device includes multiple n-type channels, rather than the single n-type channel 110. The XFETs 102 has a p-type active layer (not labeled) that includes the single p-type channel 130. In other implementations, the p-type active layer of the p-type device includes multiple p-type channels, rather than the single p-type channel 130. In the illustrated implementations, the TFETs 104 has an n-type active layer 180 that includes the n-type channel 110 and the n-type channel 111. In other implementations, the n-type active layer 180 of the n-type device includes another number of n-type channels. The TFETs 104 has a p-type active layer 182 that includes the single p-type channel 130. In other implementations, the p-type active layer 182 of the p-type device includes multiple p-type channels, rather than the single p-type channel 130.

With one or more channels, the p-type active layer 182 of the p-type device includes a three-dimensional area with dimensions such as a length, a width and a height. These dimensions correspond to the dimensions of the one or more p-type channels (or p-type nanosheets). For example, the p-type active layer length 126 is the same as the length of the one or more p-type channels such as p-type channel 130. Similarly, the n-type active layer length 124 is the same as the length of the one or more n-type channels such as the length of the n-type channel 110 or the same length of the n-type channel 111. The n-type active layer height 125 of the n-type active layer 180 is the same as the overall height of the one or more n-type channels, such as the overall height of the n-type channel 110 and the n-type channel 111. The p-type active layer width (not labeled) is the same as the width of the one or more p-type channels. Similarly, the n-type active layer width (not labeled) of the n-type active layer 180 is the same as the width of the n-type channel 110, which is the same as width of the n-type channel 111.

The n-type channel 110 and the n-type gate 116 are oriented in an orthogonal direction to the p-type channel 130 and the p-type gate 136. In other words, the n-type channel 110 and the n-type gate 116 are oriented in a direction that is 90 degrees from a direction of the p-type channel 130 and the p-type gate 136. Therefore, the direction of current flow of the bottom n-type device through the n-type channel 110 is orthogonal to the direction of current flow of the p-type channel 130 of the top p-type device. With the orthogonal orientation between the top p-type device and the bottom n-type device, both devices have the maximum mobility for their respective carriers based on their orientation. In addition, the orthogonal orientation of the top p-type device and the bottom n-type device allow connections between the vertically stacked devices to use a single via layer.

Complementary FETs (CFETs), which are not shown, include a top GAA transistor vertically stacked on top of a bottom GAA transistor with at least an oxide layer in between for isolation. Therefore, CFETs, XFETs, and TFETs use vertically stacked GAA transistors. Vertically stacking a top GAA transistor on top of a bottom GAA transistor further increases performance, reduces power consumption, reduces on-die area consumed by the GAA transistors. However, CFETs uses a top GAA transistor with one or more channels aligned in a same direction as the one or more channels of the bottom GAA transistor. CFETs do not rotate the top and bottom GAA transistors with respect to one another. However, as shown here, XFETs 102 and TFETs 104, have an orthogonal orientation between the one or more channels of the top GAA transistor and the one or more channels of the bottom GAA transistor.

Compared to Complementary FETs, XFETs 102 and TFETs 104 have better drive current for each of the top GAA transistor and the bottom GAA transistor, which leads to higher performance. Complementary FETs typically use at least two metal layers and three via layers to create connections between the top GAA transistor and the bottom GAA transistor. In contrast, XFETs 102 and TFETs 104 utilize a single metal layer and a single via layer for connections between the top and bottom GAA transistors.

Insulating layers are between the top p-type device and the bottom n-type device with a gate contact 122 formed between the devices in the insulating layers when the gate terminals of the pair of devices (the p-type device and the n-type device) receive a same input signal. The gate contact 122 between the vertically stacked devices is directly connected to the p-type metal gate 136 and the n-type metal gate 116 without traversing any metal layers. One advantage of the orthogonal orientation of the XFETs 102 and the TFETS 104 is the use of a single via layer, which is shown later in semiconductor layout of memory bit cells. The use of a single via layer reduces resistance and capacitance of a corresponding circuit.

As shown, the gate contact 122 of the XFETs 102 overlaps each of the n-type active layer and the p-type active layer of the two vertically stacked transistors. Since the illustrated implementation of the XFETs 102 includes a single channel for each of the p-type device and the n-type device, the active layers in the illustrated implementation include the single channels 110 and 130. The gate contact 122 overlaps each of the n-type channel 110 and the p-type channel 130. In contrast, the gate contact 122 of the TFETs 104 overlaps only one active layer of the p-type active layer 182 of the p-type device and the n-type active layer 180 of the n-type device where the p-type device and the n-type device form two vertically stacked devices. In the illustrated implementation, the gate contact 122 of the TFETs 104 overlaps only the n-type active layer 180 that includes the n-type channel 110 and n-type channel 111. Therefore, the gate contact 122 of the TFETs 104 overlaps only the n-type active layer 180. The gate contact 122 of the TFETs 104 does not overlap the p-type active layer 182.

For the TFETs 104, in various implementations, the p-type active layer 182 does not overlap the n-type active layer 180. A distance between the p-type active layer 182 and the n-type active layer 180 is shown as the width (or offset) 106. The width 106 includes at least a width of a source contact or a drain contact. In some implementations, the width 106 also includes another minimum distance between the p-type channel 130 and a source or drain contact that is determined by design rules and checks of the particular semiconductor fabrication process used to fabricate the TFETs 104. In an implementation, this minimum distance is 3 nanometers (nm) and a width of a source or drain contact is 18 nm. In such an implementation, the minimum width for the width 106 is 21 nm (3 nm+18 nm is 21 nm).

A top view of the TFETs 104 illustrates that the gate terminals (gates 116 and 136) of the top and bottom GAA transistors form a T-shape. The placement of the single gate contact 122 overlapping only one active layer (such as only the n-type active layer 180) of the n-type active layer 180 and the p-type active layer 182 simplifies semiconductor fabrication and improves fabrication yield when compared to placing the single gate contact 122 in a manner that overlaps both the n-type active layer and the p-type active layer as shown in the XFETs 102.

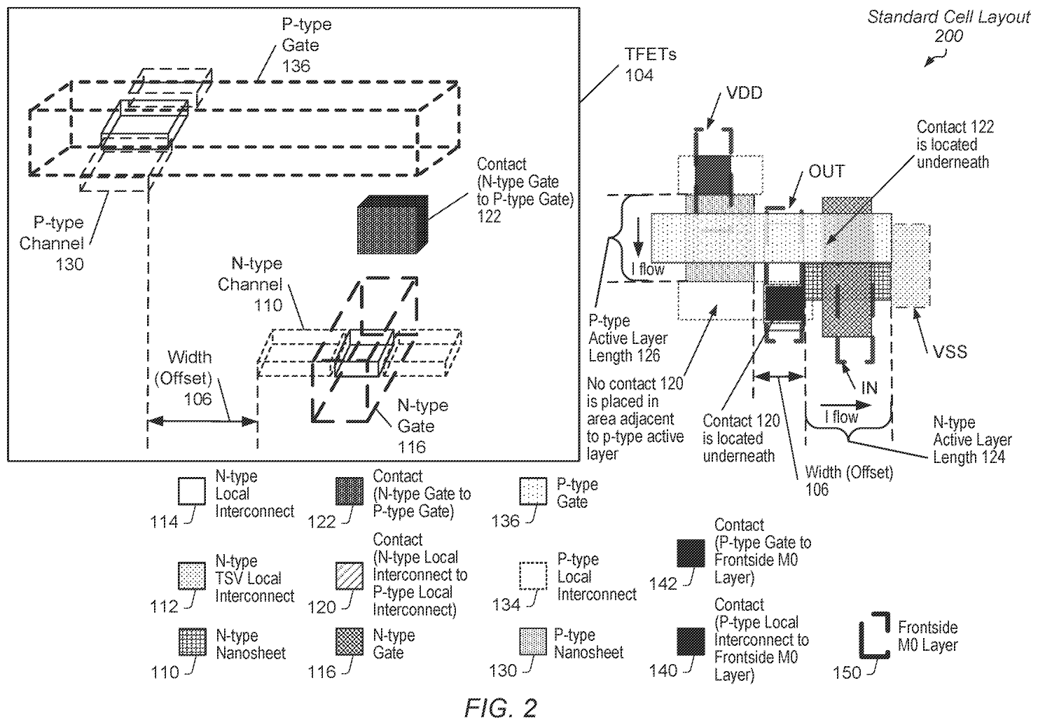

Referring to FIG. 2, a generalized block diagram of a top view of semiconductor device layout 200 is shown that uses TFETs. Contacts (or vias), semiconductor materials, and structures described earlier are numbered identically. The standard cell layout 200 is for an inverter using TFETs 104. A three-dimensional (3-D) illustration of the p-type and n-type TFETs accompanies the layout 200. The top view of the semiconductor device layout 200 (or layout 200) is shown on the right, and the cross-sectional view of the TFETs 104 is shown on the left. For this inverter, a p-type device is being vertically stacked on an n-type device. However, in other implementations, it is possible and contemplated to have an n-type device vertically stacked on a p-type device. Each of the devices of the inverter uses gate all around (GAA) metal that wraps around one or more nanosheets in the gate region in a 360-degree manner. The bottom n-type device is fabricated on a first wafer. The top p-type device is fabricated on a separate second wafer, which is then oxide to oxide bonded to the first wafer. As shown, the gate contact 122 overlaps only one active layer of the n-type active layer and the p-type active layer. The length dimensions 124 and 126 are shown in addition to the direction of current flow (I flow) of the two devices. The width 106 includes at least a width of a source or drain contact 120. Here, the inverter uses the contact 120 as a drain contact.

The inverter uses a frontside power metal zero (or metal 0 or M0 or Metal0) layer 150 to provide a power supply reference level indicated as “VDD.” The contact 140 connects the frontside M0 layer 150 to the p-type local interconnect 134 in order to route VDD to the source region of the p-type device. The frontside M0 layer 150 is also used to route the input signal “IN” and the output signal “OUT.” For the input signal “IN,” contact 142 connects the frontside M0 layer 150 to the p-type gate 136. For the input signal “IN,” contact 122 connects the p-type gate 136 to the n-type gate 116. The drain region of the n-type device uses the n-type local interconnect 114. The drain region of the p-type device uses the p-type local interconnect 134. Contact 120 connects these two drain regions together.

The contact 120 is located between the drain nodes of the p-type transistor and the n-type transistor and contacts an area of the p-type local interconnect 134 of the p-type transistor. This area of the local interconnect layer 134 is not physically adjacent to the p-type active layer of the p-type transistor. Since the contact 120 has this placement, the contact 120 provides a lower resistance contact between the p-type local interconnect 134 and the n-type local interconnect 114. In addition, the placement of the contact 120 provides higher reliability (less process variation) and higher fabrication yield than if the contact 120 was placed along an area of the p-type local interconnect 134 physically adjacent to the p-type active layer. The techniques shown in the layout 200 are used again in the upcoming layouts 500-1200 and 1100-2300 that provides standard cell layout of memory bit cells that includes the benefits of the TFETs 104.

For the output signal “OUT,” contact 140 overlaps the area of the contact 120, and connects the p-type local interconnect 134 to the frontside M0 layer 150. The inverter uses a backside power metal zero (or metal 0 or M0 or Metal0) layer located below the silicon substrate layer and any oxide layer (not shown), which is used for isolation. A micro through silicon via (TSV) traverses the silicon substrate layer in order to be placed between the backside power M0 rail and the source region of the n-type device.

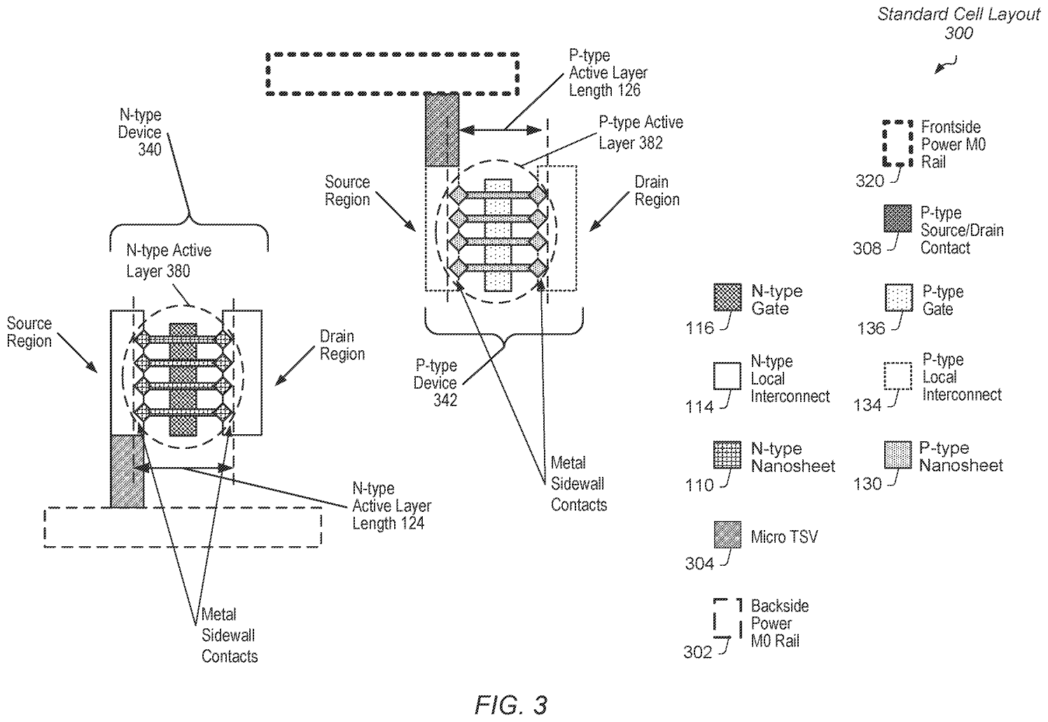

Referring to FIG. 3, a generalized block diagram is shown of a cross-section view of a standard cell layout 300 that utilizes power connections routed in a frontside metal layer and a backside metal layer. Contacts (or vias), semiconductor materials, and structures described earlier are numbered identically. The standard cell layout 300 is for any of a variety of types of Boolean gates and complex gates that include transistors arranged in a particular manner for providing data processing functionality or providing data storage. The standard cell layout 300 (or layout 300) uses TFETs. The TFETs include the n-type device 340 and the p-type device 342. Although the cross-section view shows each of the two transistors (devices) 340 and 342 with metal gates oriented in a same direction, the actual placement of these transistors in semiconductor layout includes orthogonal placement with respect to one another. Power signals are routed using both frontside and backside metal layers.

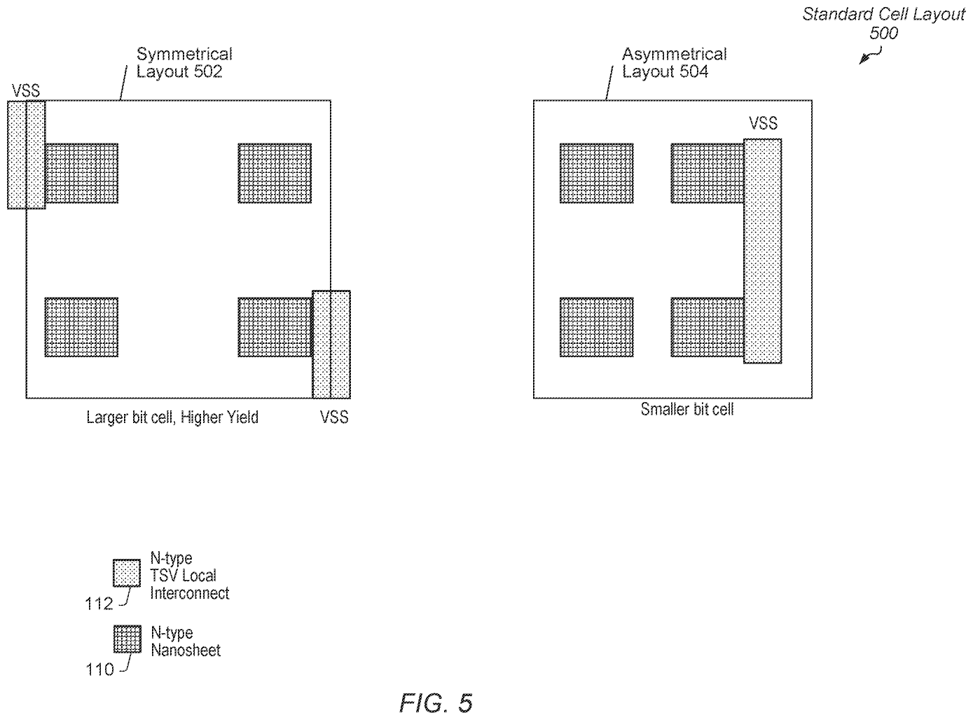

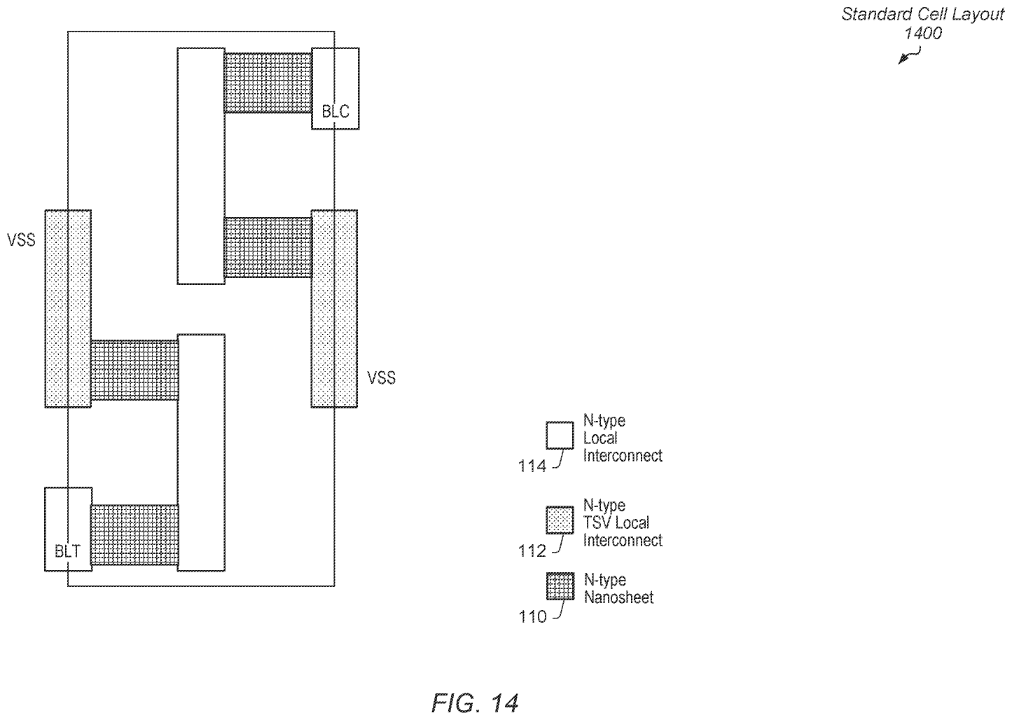

Here, a first transistor of the TFETs, such as the n-type device 340, has an n-type active layer 380 that provides current flow oriented in a first direction orthogonal to a second direction of current flow in the p-type active layer 382. In an implementation, the n-type active layer 380 includes multiple n-type nanosheets. In the key or legend, the label “n-type nanosheet 110” is used. However, it is understood that an n-type active layer, such as the n-type active layer 380 (and n-type active layer 180 of FIG. 1) can include multiple n-type nanosheets as shown in the cross-section view provided in layout 300. The upcoming layouts 500-1200 (of FIGS. 5-12) and 1400-2300 (of FIGS. 14-23) provide a top view, rather than a cross-section view, and accordingly, only a single n-type nanosheet is shown. However, it is understood that one or more additional n-type nanosheets are formed underneath the topmost n-type nanosheet as shown in layout 300 and layout 100 (of FIG. 1). The same is true for the p-type nanosheet 130.

In various implementations, each of the n-type nanosheets 110 of the n-type active layer 380 consists of a silicon semiconducting epitaxial growth layer doped with n-type atoms. Similarly, each of the p-type nanosheets 130 consists of a silicon semiconducting epitaxial growth layer doped with p-type atoms. Each of the n-type nanosheets 110 and the p-type nanosheets 130 ends within the edges of their respective drain region and source region. The drain region and source region of the n-type device 340 uses the n-type local interconnect 114 shown earlier. The drain region and source region of the p-type device 342 uses the p-type local interconnect 134 shown earlier. In contrast to Complementary FETs, the n-type nanosheets 110 do not traverse the entirety of the drain region and the source region. Rather, the n-type nanosheets 110 utilize metal sidewall contacts at the ends of the nanosheets within the source region and the drain region, which allows more nanosheets to be created in the n-type active layer. The p-type nanosheets 130 of the p-type active layer 382 are formed in a similar manner and also utilize metal sidewall contacts at the ends of the nanosheets within the respective source region and drain region.

As described earlier, the n-type active layer 380 refers to a region of a semiconductor wafer where doped silicon is formed. The n-type active layer 380 of the n-type device 340 is a three-dimensional area that includes a length equal to the distance between the metal sidewall contacts at the ends of the nanosheets within the source region and the drain region. This n-type active layer 380 has a height equal to the distance from the bottom of the bottom n-type nanosheet 110 to the top of the top n-type nanosheet 110. Additionally, this n-type active layer 380 has a width equal to the distance that the n-type nanosheets 110 traverse along a direction going into the page (or out of the page). The p-type active layer 382 of the p-type device 342 has dimensions defined in a similar manner.

The n-type device 340 is connected to a first voltage level reference provided by a backside metal layer. This backside power metal zero (or metal 0 or M0 or Metal0) layer 302 is located below the silicon substrate layer and any oxide layer (not shown), which is used for isolation. A micro through silicon via (TSV) 304 traverses the silicon substrate layer in order to be placed between the backside power M0 layer 302 and the source region of the n-type device 340. The TFETs also use a second transistor, such as the p-type device 342, having a second channel oriented in a second direction orthogonal to the first direction and connected to a second voltage level reference provided by a frontside metal layer. This frontside power metal zero (or metal 0 or M0 or Metal0) layer 320 is located above the silicon substrate layer and any oxide layer (not shown), which is used for isolation. The drain region and source region of the p-type device 342 uses the p-type local interconnect 134 shown earlier. In other implementations, the n-type transistor 340 and the p-type transistor 342 are switched along with the types of voltage reference levels connected to the backside power M0 layer 302 and the frontside power M0 layer 320.

The “micro TSV” 304 is a through silicon via that traverses through the silicon substrate layer from the backside power M0 layer 302 to the source region 306, and ends with physical contact at each of the backside power M0 layer 302 to the source region 306. The distance between the backside power M0 layer 302 to the n-type local interconnect 114 used as the source region defines the height or length of the micro TSV 304, which traverses only the silicon substrate layer and any oxide layer above the backside power M0 layer 302. The micro TSV 304 does not physically extend into multiple insulation layers of a semiconductor die used for routing multiple frontside metal layers. Similarly, the micro TSV 304 does not physically extend into multiple insulation layers of the semiconductor die used for routing multiple backside metal layers.

Although the orientation of the standard cell layout 300 (or layout 300) is shown to have each of the backside power M0 layer 302 and the frontside power M0 rail 320 routed in the horizontal direction, other orientations are possible and contemplated. It is understood that a silicon wafer, an integrated circuit, and a semiconductor package using the silicon substrate layer can be rotated and flipped. Therefore, the materials and layers being described would be rotated and flipped, and the orientations and directions would have a different meaning. Therefore, the terms “top,” “bottom,” “horizontal,” “vertical,” “above,” and “below” can change as the layout 100 is rotated or flipped, and the use of these terms in the below description correspond to the orientation being shown in the layout 300.

As used herein, a “terminal” of a transistor is also referred to as a “region” of a transistor. For example, a source region is also referred to as a source terminal, a drain region is also referred to as a drain terminal, and a gate region is also referred to as a gate terminal. The source and drain regions are typically formed in a same orientation (horizontal or vertical) as corresponding gate metal of a same device. Examples of the source and drain regions are trench silicide contacts. In some implementations, the source and drain regions include Cobalt silicide (CoSi₂). In other implementations, the source and drain regions include Titanium silicide (TiSi₂) or ruthenium (Ru).

To transport current from an off-chip power supply to p-type device 342, the current flows from the off-chip power supply to multiple frontside metal layers to the frontside power M0 layer 320 to the p-type source contact 308 of the p-type device 342. To transport current from an off-chip ground reference to n-type device 340, the current flows from the off-chip ground reference to one or more backside metal layers to the backside power M0 layer 302 to the n-type local interconnect 114 used as the source region of the n-type device 340. In some implementations, a single, thick backside metal layer is used to transport the ground reference, rather than multiple, think backside metal layers to reduce semiconductor fabrication costs. The power connections shown in layout 300 reduces on-die area, reduces semiconductor fabrication complexity, which improves wafer yield, and reduces voltage droop, which increases performance.

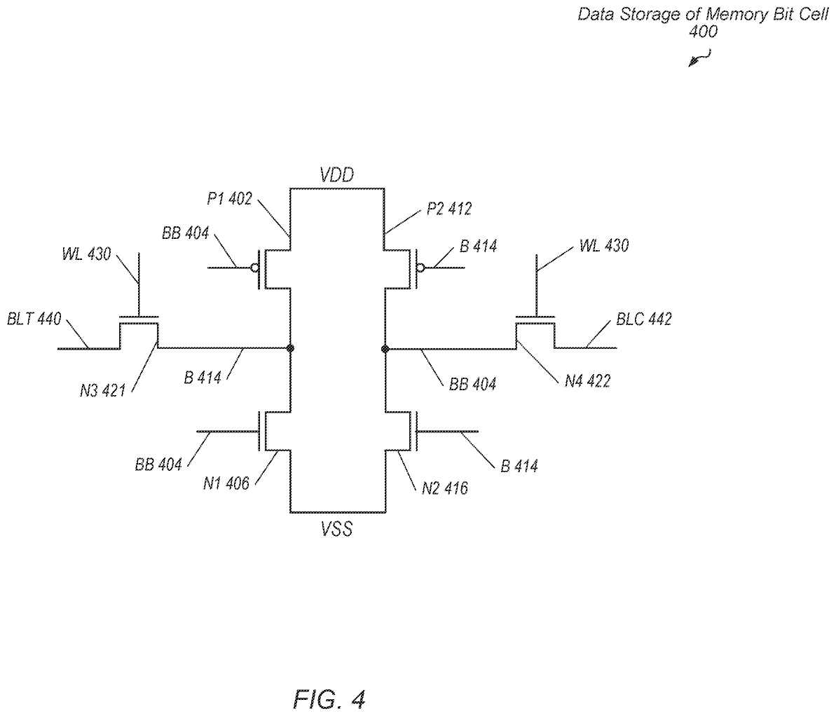

Turning to FIG. 4, a generalized block diagram of one implementation of data storage of a memory bit cell 400 is shown. In the implementation shown, data storage by a latching element is provided by the devices P1 402, N1 406, P2 412 and N2 416. These devices provide data storage using a back-to-back configuration of two inverters. The back-to-back configuration of two inverters is also referred to as cross-coupled inverters. As used herein, a Boolean logic high level is also referred to as a logic high level. Similarly, a Boolean logic low level is also referred to as a logic low level. In various implementations, the logic high level is equal to a power supply reference voltage level and the logic low level is equal to a ground reference voltage level. As used herein, a circuit node or line is “asserted” when the node or line stores a voltage level that enables a transistor that receives the voltage level, or the voltage level indicates an operation is enabled. For example, an n-type transistor is enabled when the n-type transistor receives a positive non-zero voltage level on its gate terminal that is at least a threshold voltage above a voltage level on its source terminal.

As used herein, the circuit node or line is “negated” when the node or line stores a voltage level that disables a transistor that receives the voltage level. An n-type transistor is disabled when the n-type transistor receives a voltage level on its gate terminal that is within a threshold voltage of a voltage level on its source terminal. Similarly, a p-type transistor is enabled when the p-type transistor receives a voltage level on its gate terminal that is at least a threshold voltage below a voltage level on its source terminal. The p-type transistor is negated when the p-type transistor receives a voltage level on its gate terminal that is within a threshold voltage of a voltage level on its source terminal. Additionally, operations are enabled and disabled based on corresponding control signals being asserter or negated.

When a write operation is occurring, external circuitry (not shown) asserts the write word line WL 430 with a logic high level. Accordingly, each of the n-type transistors N3 421 and N4 422 is enabled. The enabled transistor N3 421, which is a pass gate, electrically connects the bit line BLT (Bit Line True) 440 to the node B 414. The enabled transistor N4 422, which is a pass gate, electrically connects the bit line BLC (Bit Line Complement) 442 to the node BB 404. In various implementations, during the write operation, external circuitry ensures the BLC 442 has an opposite (complemented) Boolean value compared to a Boolean value for the BLT 440. Therefore, the bit line BLT 440 drives a voltage level to be stored on the node B 414. One of the transistors P2 412 and N2 416 is enabled based on the voltage level of the node B 414. Similarly, one of the transistors P1 402 and N1 406 is enabled based on the node BB 404, which is the output node between the two transistors P2 412 and N2 416.

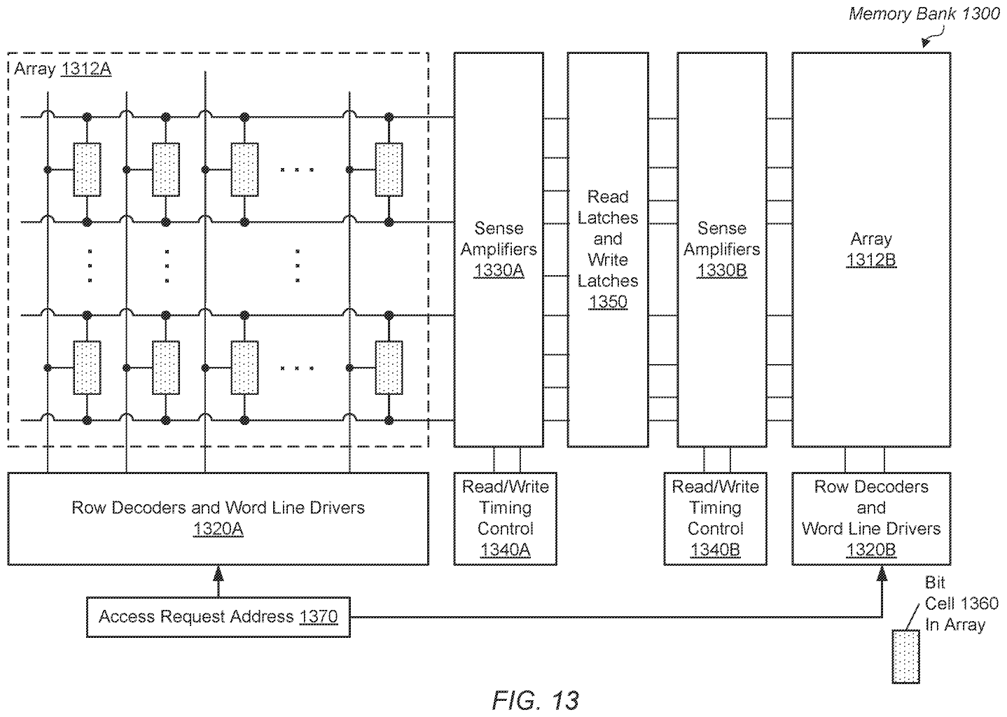

When a write operation is not occurring, external circuitry (not shown) negates the write word line WL 430 with a logic low level. Accordingly, each of the n-type transistors N3 421 and N4 422 is disabled. The data storage of the memory bit cell 400 is one implementation of a static RAM (SRAM). In other implementations, another one of various types of RAM cells is used. This “memory bit cell” is also be referred to as the “memory bit cell,” the “SRAM bit cell,” and “bit cell.” In various implementations, the memory bit cell 400 is copied many times and arranged in rows and columns of a memory array as shown later in memory bank 1300 (of FIG. 13). In various implementations, the memory bit cell 400 includes TFETs and layout techniques of cell layout 500-1200 (of FIGS. 5-12) and cell layout 1400-2300 (of FIGS. 14-23) in the upcoming description. These layout techniques are used for forming a six transistor (6T) random access data storage of a memory bit cell.

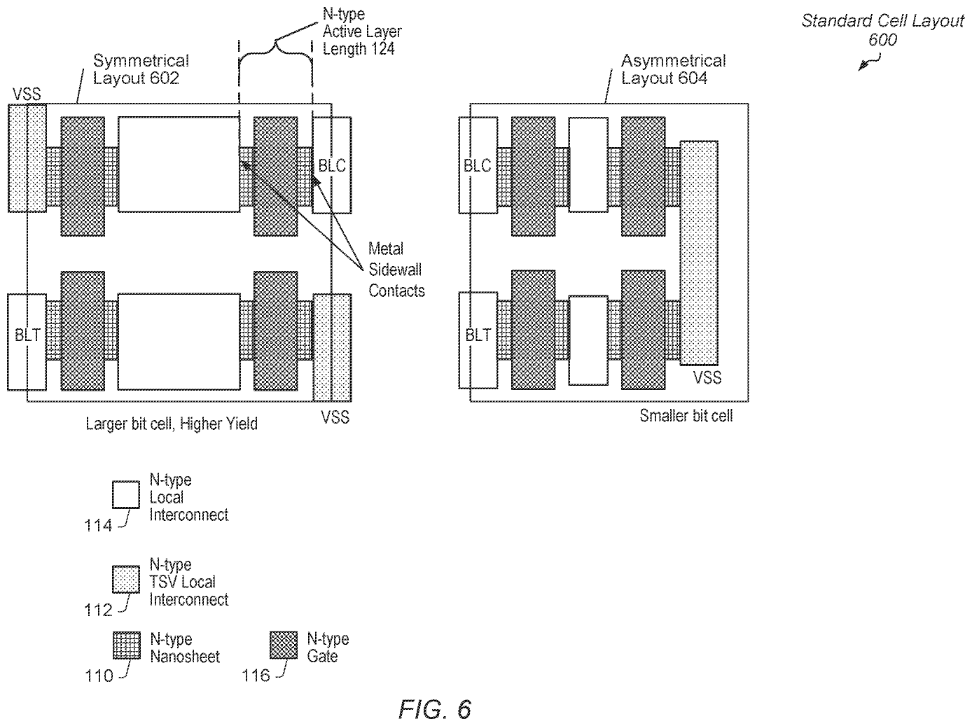

Turning now to FIG. 5, a generalized block diagram is shown of a top view of a standard cell layout 500. Contacts (or vias), semiconductor materials, and structures described earlier are numbered identically. The standard cell layout 500 (or layout 500) is for a memory bit cell using TFETs 104 (of FIG. 1). The layout 500 includes the symmetrical layout 502 (or layout 502) and the asymmetrical layout 504 (or layout 504). Each of the layout 502 and the layout 504 is for a corresponding memory bit cell that uses TFETs. The layout 502 uses symmetrical placement of materials and electrical nodes and signals, which provides higher semiconductor fabrication yield. The layout 504 uses asymmetrical placement of materials and electrical nodes and signals, which provides a smaller standard cell. Therefore, the tradeoff between using the layout 502 and the layout 504 is selecting higher yield or a smaller memory bit cell. Similarly, the layout 602-1202 (of FIGS. 6-12) use symmetrical placement of materials and electrical nodes and signals, which provides higher semiconductor fabrication yield. The layout 604-1204 (of FIGS. 6-12) use asymmetrical placement of materials and electrical nodes and signals, which provides a smaller standard cell.

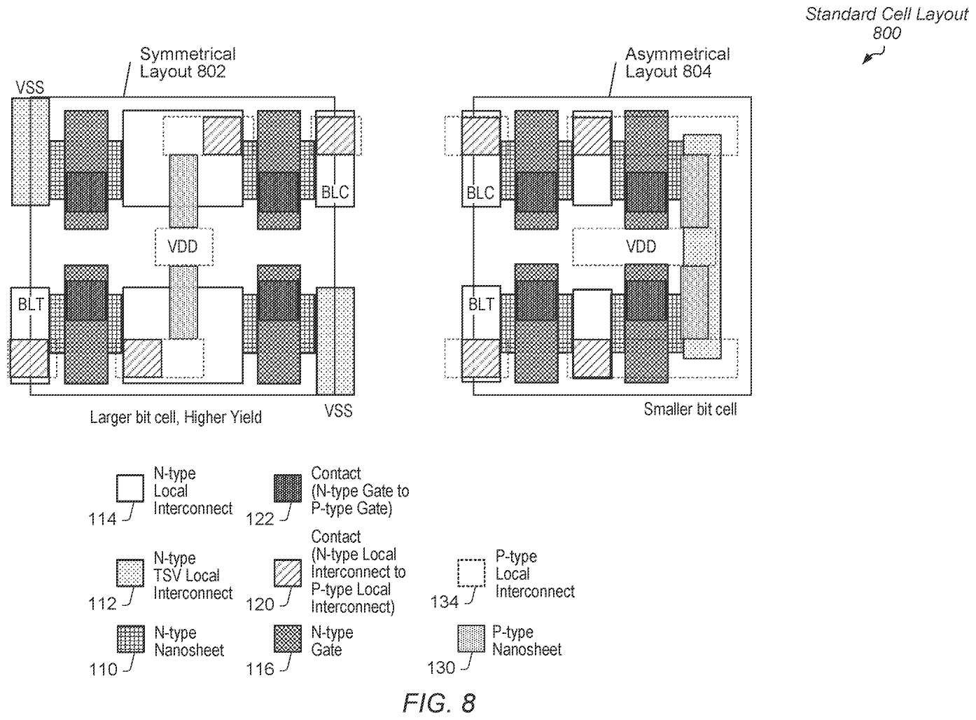

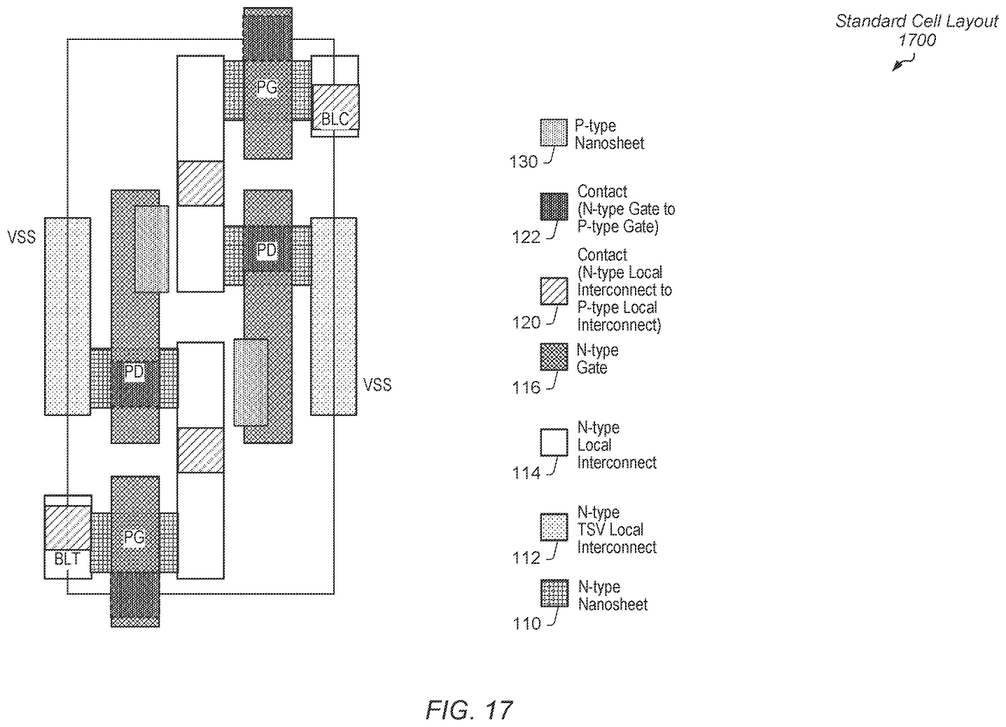

Here, in both the layout 502 and 504, the n-type nanosheets 110 are created from a stack of alternating layers such as a silicon germanium semiconducting epitaxial growth layer alternating with a silicon semiconducting epitaxial growth layer. As described earlier, the layouts 500-1200 (of FIGS. 5-12) and 1400-2300 (of FIGS. 14-23) provide a top view, rather than a cross-section view, and accordingly, only a single n-type nanosheet is shown. However, it is understood that one or more additional n-type nanosheets are formed underneath the topmost n-type nanosheet as shown in layout 300 (of FIG. 3) and layout 100 (of FIG. 1). The same is true for the p-type nanosheet 130 that is shown in layouts 800-1200 (of FIGS. 8-12) and 1700-2300 (of FIGS. 17-23).

For the n-type nanosheet 110, the stack of alternating layers is etched to the size of the n-type nanosheets 110 using one of a sidewall image transfer (SIT) process, extreme ultraviolet (EUV) lithography, directed self-assembly (DSA) patterning via chemo epitaxy or self-aligned customization. In other implementations, the alternating layers are grown on top of a silicon on insulator (SOI) oxide layer followed by an etching step. A given conduction layer of the alternating silicon germanium semiconducting epitaxial growth layer and silicon semiconducting epitaxial growth layer is selected to remain for forming the gate region. Afterward, any semiconducting layer other than the selected layer is removed. The n-type TSV local interconnect 112 is formed in the locations where later connections to a micro TSV are placed.

Turning now to FIGS. 6-12, generalized block diagrams are shown of a top view of a standard cell layouts 600-1200 (or layouts 600-1200). Contacts (or vias), materials and structures described earlier are numbered identically. In the layout 600, the n-type source and drain regions are formed. In an implementation, the n-type source and drain regions are epitaxially grown silicon doped with Phosphorous. Afterward, the n-type local interconnect 114 is formed. In some implementations, n-type local interconnect 114 includes the tungsten, cobalt, ruthenium, or molybdenum.

Gate metal material 116 is deposited followed by chemical mechanical planarization (CMP) steps to polish the n-type gate metal 116. In various implementations, titanium nitride (TiN) is used for the gate metal 116. The gate metal 116 is provided all around the n-type nanosheets 110 in a 360-degree manner. An interlayer dielectric (ILD) oxide layer is deposited around the gate region. The label “BLT” corresponds to the BLT 440 signal of the memory bit cell 400 (of FIG. 4). Similarly, the label “BLC” corresponds to the BLC 442 signal of the memory bit cell 400 (of FIG. 4). In addition, the layout 604 includes the n-type TSV local interconnect 112 along a length of an entire side of the layout 604, whereas, the layout 602 includes the n-type TSV local interconnect 112 in corners of the layout 602. Although not shown, the n-type local interconnect 114 covers the n-type TSV local interconnect 112.

The layout 700 has the contacts 120 (n-type local interconnect to p-type local interconnect connections) formed and gate contacts 122 formed. However, only two of the gate contacts 122 are to be connected to the p-type gate 136 such as n-type gates for pull down devices (transistors). The layout 800 has the p-type channel 130 (or p-type nanosheet 130) formed followed by the p-type local interconnect 134. Etching of the oxide layer and deposition of corresponding materials is performed to form these p-type local interconnect 134 layers. The layout 900 has the p-type gate 136 formed. For example, the p-type gate metal material 136 is deposited followed by chemical mechanical planarization (CMP) steps to polish the p-type gate metal 136. In various implementations, titanium nitride (TiN) is used for the p-type gate metal 136. The layout 900 also has the contacts 140 formed. The label “PD” indicates a pulldown n-type device such as the N1 406 device and the N2 416 device of the memory bit cell 400 (of FIG. 4). The label “PU” indicates a pullup p-type device such as the P1 402 device and the P2 412 device of the memory bit cell 400 (of FIG. 4).

The layout 1000 has the contacts 142 formed. For the symmetrical layout 1002, the non-overlapping distance between the p-type active layer and the n-type active layer is shown as the width (or offset) 106. This width 106 is between the p-type active layer of a p-type pullup device and the n-type active layer of an n-type pass gate device. Examples of these devices are the p-type device P2 412 and the n-type device N4 422 of the memory bit cell 400 (of FIG. 4). It is noted that the n-type nanosheet (n-type active layer) of the n-type pulldown device located to the left of the p-type pullup device also shares this drain node (this n-type local interconnect 114). An example of this n-type pulldown device is the n-type device N2 416 of the memory bit cell 400 (of FIG. 4). The non-overlapping distance between the p-type active layer of the p-type pullup device and the n-type active layer of the n-type pulldown device can also be the width (or offset) 106.

The width 106 includes at least a width of a source contact or a drain contact such as the contact 120 used as a drain contact between the p-type pullup device and the n-type pass gate device. Although this node can also be a source region for the n-type pass gate device when the node has a logic low value and the signal BLC has a logic high value. In some implementations, the width 106 also includes another minimum distance between the p-type nanosheet 130 and the drain contact 120 that is determined by design rules and checks of the particular semiconductor fabrication process used to fabricate the TFETs 104. Between the drain nodes of the p-type pullup device and the n-type pass gate device is the drain contact 120 making contact with an area of the p-type local interconnect 134 of the p-type pullup device. This area of the p-type local interconnect layer 134 is not physically adjacent to the p-type nanosheet 130 (the p-type active layer) of the p-type pullup device. Since the drain contact 120 has this placement, the drain contact 120 provides a lower resistance contact between the p-type local interconnect 134 and the n-type local interconnect 114.

In the case of the asymmetrical layout 1004, the placement of the p-type pullup device is to the right of the n-type pulldown device. The n-type pass gate device is located to the far left of the layout 1004. In contrast to the symmetrical layout 1002, the p-type pullup device is not adjacent to the n-type pass gate device in the asymmetrical layout 1004. Similar to the symmetrical layout 1002, the drain contact 120 of the asymmetrical layout 1004 makes contact with an area of the p-type local interconnect 134, and this area is not physically adjacent to the p-type nanosheet 130 (the p-type active layer) of the p-type pullup device. Since the drain contact 120 has this placement, the drain contact 120 provides a lower resistance contact between the p-type local interconnect 134 and the n-type local interconnect 114.

In contrast to the symmetrical layout 1002, a non-overlapping distance between the p-type nanosheet 130 of the p-type pullup device and the n-type nanosheet 110 of the neighboring (although vertically below) n-type pulldown device is less than the width (or offset) 106. The p-type local interconnect 134 that provides the drain node of the p-type pullup device extends to the left past the n-type nanosheet 110 of the n-type pulldown device to provide a location for the drain contact 120. In contrast to the symmetrical layout 1002, this drain contact 120 of the asymmetrical layout 1004 is not physically located between the p-type nanosheet 130 of the p-type pullup device and the n-type nanosheet of the n-type pulldown device. Similar to the symmetrical layout 1002, the gate contact 122 used by the p-type gate 136 of the p-type pullup device and the n-type gate 116 of the n-type pulldown device partially overlaps the n-type nanosheet 110 of the n-type pulldown device, but does not overlap the p-type nanosheet 130 of the p-type pullup device.

In the layout 1100, the frontside M0 layer 150 is formed to complete create signal connections of the 6T random access data storage of a memory bit cell. The label “WL” corresponds to the WL 430 signal of the memory bit cell 400 (of FIG. 4). Continuing with the signal connections, the layout 1200 has vias 160 formed to connect the frontside M0 layer 150 to a metal one layer (or metal1 or Metal 1 or M1) 170. The M1 170 layer is deposited afterward for creating even further connections for the bit cell.

Turning now to FIG. 13, a generalized block diagram of one implementation of a memory bank 1300 is shown. In various implementations, a memory is organized as multiple memory banks, and a memory macro block includes both a left bank and a right bank. In some implementations, the bank 1300 is one of the left bank or the right bank of the memory macro block. Although “left” and “right” are used to describe the memory banks, other notations can be used such as a “top bank” and a “bottom bank.” As shown, the memory bank 1300 includes arrays 1312A-1312B, row decoders 1320A-1320B, sense amplifiers 1330A-1330B between the arrays 1312A-1312B, read and write timing control logic 1340A-1340B, and read latches and write latches in block 1350. It is noted that, in some implementations, multiple banks are accessed concurrently in a same clock cycle or a same pipeline stage. The access includes one of a read access and a write access. In such implementations, bank address decoders select the corresponding banks to access.

In various implementations, each of the blocks 1312A-1312B, 1320A-1320B, 1330A-1330B, 1340A-1340B and 1350 in the memory bank 1300 is communicatively coupled to another one of the blocks. For example, direct connections are used wherein routing occurs through another block. Alternatively, staging of signals is done in an intermediate block. In various implementations, each of the arrays 1312A-1312B includes multiple memory bit cells 1360 (or bit cells 1360) arranged in a tiled format. Here, the rows are aligned with the tracks used for the routing of the word lines of the array such as in the vertical direction in the illustrated implementation. The columns are aligned with the tracks used for the routing of the bit lines of the array such as in the horizontal direction in the illustrated implementation. In other implementations, the rows and columns are rotated and have a different orientation.

The row decoders and word line drivers in blocks 1320A-1320B receive address information corresponding to an access request. For example, each of the blocks 1320A-1320B receives the information provided by the access request address 1370. Each one of the blocks 1320A-1320B selects a particular row, or entry, of the multiple rows in an associated one of the arrays 1312A-1312B. In some implementations, the blocks 1320A-1320B use an index portion of the address 1370 for selecting a given row, or entry, in an associated one of the arrays 1312A-1312B. Each row, or entry, stores one or more memory lines.

In the implementation shown, the rows, or entries, in the arrays 1312A-1312B are arranged in a vertical orientation. However, in other implementations, a horizontal orientation is used for storage of the memory lines. For write access requests, the write latches are located in block 1350. The write data is driven into the arrays 1312A-1312B. The timing control logic 1340A-1340B updates the write latches with new data in block 1350 and sets up the write word line driver logic. The write data is written into a row of bit cells that is selected by an associated one of the blocks 1320A-1320B. In some implementations, pre-charge circuitry is included in block 1350.

For read access requests, the block 1350 is used to pre-charge the read bit lines routed to the arrays 1312A-1312B. The timing circuitry in blocks 1340A-1340B is used for pre-charging and setting up the sense amplifiers in the blocks 1330A-1330B. The timing circuitry 1340A-1340B sets up the read word line driver logic. One of the row decoders 1320A-1320B selects a row to read out data, which will be provided on read bit lines that are sensed by the sense amplifiers. The read latches capture the read data.

In various implementations, the memory bit cell 1360 (or bit cell 1360) utilizes a six transistor (6T) random access data storage. For example, data storage uses a back-to-back configuration of two inverters (cross-coupled inverters). In various implementations, the memory bit cell 1360 (or bit cell 1360) utilizes the data storage circuit configuration of bit cell 400 (of FIG. 4) and the layout techniques of standard cell layouts 600-1200 (of FIGS. 6-12) and standard cell layouts 1100-2300 (of FIGS. 14-23).

Turning now to FIGS. 14-23, generalized block diagrams are shown of top views of standard cell layouts 1100-2300 (or layouts 1100-2300). Contacts (or vias), materials, and structures described earlier are numbered identically. Additionally, labels described earlier use the same names. In the layout 1400, the n-type nanosheets 110 are created, the n-type TSV local interconnect 112 is formed in the locations where later connections to a micro TSV are placed, and the n-type local interconnect 114 is formed. Although not shown, the n-type local interconnect 114 covers the n-type TSV local interconnect 112. In the layout 1500, the n-type gates 116 are deposited, and the gate contacts 120 are formed.

The layout 1600 has the gate contacts 122 formed. However, only two of the gate contacts 122 are to be connected to the p-type gate 136 such as n-type gates for pull down devices (transistors). The layout 1700 has the p-type channel 130 (or p-type nanosheet 130) formed. Following, the p-type local interconnect 134 is formed in the layout 1800. The layout 1800 also has the p-type gate 136 formed.

The layout 1900 has the contacts 140 formed. The layout 2000 has the contacts 142 formed. In the layout 2100, the frontside M0 layer 150 is formed to complete create signal connections of the 6T random access data storage of a memory bit cell. Continuing with the signal connections, the layout 2200 has vias 160 formed to connect the frontside M0 layer 150 to a metal one layer (or metal1 or Metal 1 or M1) 170. In the layout 2300, the M1 170 layer is deposited afterward for creating even further connections for the bit cell. The M1 170 layer provides connections for the word line (WL) signal and the power supply reference levels (VDD and VSS). In contrast to the symmetrical layout 1202 and the asymmetrical layout 1204, the layout 2300 does not use the M1 170 layer for the bit lines (BLT and BLC). As a result, the dimensions of the on-die area of the layout 2300 is different from either of the layout 1202 and the layout 1204. For example, a first height of the layout 1202 contributing to an on-die area of this memory bit cell layout 1202 is less than a second height of the layout 2300 contributing to an on-die area of this memory bit cell layout 2300. A first width of the layout 1202 contributing to the on-die area of this memory bit cell layout 1202 is greater than a second width of the layout 2300 contributing to the on-die area of this memory bit cell layout 2300. Similar height and width relations also exist between the layout 1204 and the layout 2300.

The layout 500-1200 and 1400-2300 provides standard cell layout that includes the benefits of the TFETs 104. For example, the n-type channel 110 (n-type nanosheets) and the p-type channel 130 (p-type nanosheets) are shifted from one another. The semiconductor fabrication is simplified, which increase yield. A less complicated selective etch bias process can be used, and there are less materials used compared to Complementary FETs and XFETs 102. The width 106 illustrates this shift. The gate terminals of the p-type device and the n-type device of TFETs form a T-shape, rather than an X-shape. The p-type local interconnect 134 extends beyond the p-type channel 130 (the p-type active layer) before having a contact 120 placed for connecting to the n-type local interconnect 114. The placement of the contact 120 on the p-type local interconnect 134 in the layout 200 (of FIG. 2) illustrates one example of such a placement of a drain contact. The contact used to connect the p-type local interconnect 134 to the n-type gate 116 has been eliminated and replaced by contact 120 when both p-type gate 136 overlaps the n-type gate 116. Compared to the Complementary FETs and XFETs 102, the TFETs 104 have lower resistance and capacitance. The shifting of the n-type channel 110 and the p-type channel 130 that creates the width 106 also increases thermal heat spreading.

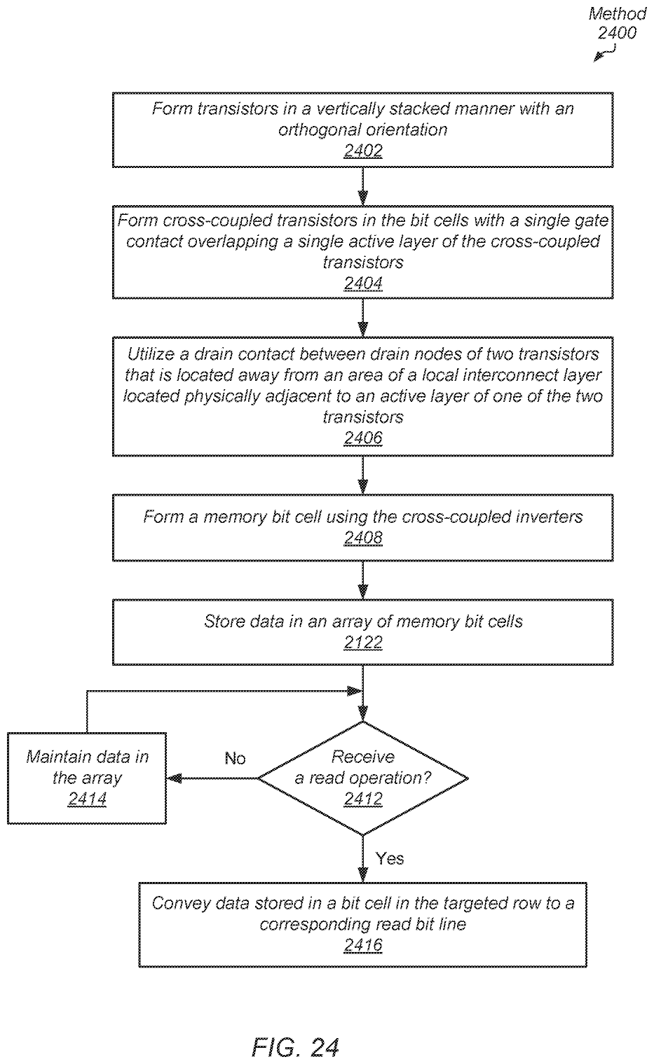

Referring now to FIG. 24, a generalized block diagram is shown of a method 2400 for efficiently creating layout for memory bit cells. For purposes of discussion, the steps in this implementation are shown in sequential order. However, in other implementations some steps occur in a different order than shown, some steps are performed concurrently, some steps are combined with other steps, and some steps are absent.

A semiconductor fabrication processor (or process) forms transistors in a vertically stacked manner with an orthogonal orientation (block 2402). The process forms cross-coupled transistors in the bit cells with a single gate contact overlapping a only one active layer of the two active layers of the cross-coupled inverters (block 2404). The placement of the contact 122 in the layout 200 (of FIG. 2) illustrates one example of such a placement of a gate contact. The process forms, between drain nodes of two transistors, a drain contact contacting an area of a local interconnect layer of a particular transistor of the two transistors. This area of the local interconnect layer is not physically adjacent to the active layer of the particular transistor. (block 2406). The placement of the contact 120 on the p-type local interconnect 134 in the layout 200 (of FIG. 2) illustrates one example of such a placement of a drain contact. The process forms a memory bit cell using the cross-coupled inverters (block 2408).

An array of these memory bit cells is arranged as multiple rows and columns stores data (block 2410). In various implementations, the values of the stored data are maintained by data storage loops within the memory bit cells. In addition, the values of the stored data are updated by write operations. If the array does not receive a read operation (“no” branch of the conditional block 2412), then each of the bit cells maintains a stored binary value (block 2414). For example, each of the bit cells includes a latch element for storing the binary value until the binary value is modified by a write access operation. If the array receives a read operation (“yes” branch of the conditional block 2412), then a bit cell in a row targeted by the read operation conveys data stored in the bit cell to a corresponding read bit line (2416).

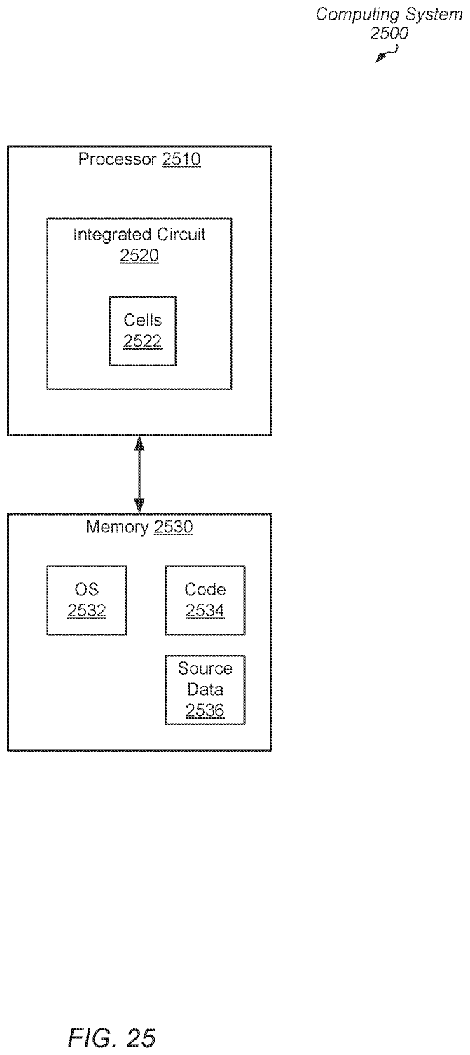

Referring to FIG. 25, a generalized block diagram is shown of a computing system 2500 is shown. The computing system 2500 includes the processor 2510 and the memory 2530. Interfaces, such as a memory controller, a bus or a communication fabric, one or more phased locked loops (PLLs) and other clock generation circuitry, a power management unit, and so forth, are not shown for ease of illustration. It is understood that in other implementations, the computing system 2500 includes one or more of other processors of a same type or a different type than processor 2510, one or more peripheral devices, a network interface, one or more other memory devices, and so forth. In some implementations, the functionality of the computing system 2500 is incorporated on a system on chip (SoC). In other implementations, the functionality of the computing system 2500 is incorporated on a peripheral card inserted in a motherboard. The computing system 2500 is used in any of a variety of computing devices such as a desktop computer, a tablet computer, a laptop, a smartphone, a smartwatch, a gaming console, a personal assistant device, and so forth.

The processor 2510 includes hardware such as circuitry. For example, the processor 2510 includes at least one integrated circuit 2520, which utilizes TFETs for implementing memory bit cells 2522 instantiated in one or more memory arrays. In some implementations, these bit cells 2522 use the circuitry of bit cell 400 (of FIG. 4) and one or more layouts of the layouts 500-1200 (of FIGS. 5-12) and layouts 1400-2300 (of FIGS. 14-23). In various implementations, the processor 2510 includes one or more processing units. In some implementations, each of the processing units includes one or more processor cores capable of general-purpose data processing, and an associated cache memory subsystem. In such an implementation, the processor 2510 is a central processing unit (CPU). In another implementation, the processing cores are compute units, each with a highly parallel data microarchitecture with multiple parallel execution lanes and an associated data storage buffer. In such an implementation, the processor 2510 is a graphics processing unit (GPU), a digital signal processor (DSP), or other.

In some implementations, the memory 2530 includes one or more of a hard disk drive, a solid-state disk, other types of flash memory, a portable solid-state drive, a tape drive and so on. The memory 2530 stores an operating system (OS) 2532, one or more applications represented by code 2534, and at least source data 2536. Memory 2530 is also capable of storing intermediate result data and final result data generated by the processor 2510 when executing a particular application of code 2534. Although a single operating system 2532 and a single instance of code 2534 and source data 2536 are shown, in other implementations, another number of these software components are stored in memory 2530. The operating system 2532 includes instructions for initiating the boot up of the processor 2510, assigning tasks to hardware circuitry, managing resources of the computing system 2500 and hosting one or more virtual environments.

Each of the processor 2510 and the memory 2530 includes an interface unit for communicating with one another as well as any other hardware components included in the computing system 2500. The interface units include queues for servicing memory requests and memory responses, and control circuitry for communicating with one another based on particular communication protocols. The communication protocols determine a variety of parameters such as supply voltage levels, power-performance states that determine an operating supply voltage and an operating clock frequency, a data rate, one or more burst modes, and so on.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R. CD-RW. DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware based type emulator from such vendors as Cadence®, EVE®, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit comprising:
a first array of memory bit cells arranged as a plurality of rows and a plurality of columns;
wherein a first memory bit cell of the first array comprises a gate contact, between a first gate of a first transistor and a second gate of a second transistor, that overlaps only one active layer of a first active layer of the first transistor and a second active layer of the second transistor.

2. The integrated circuit as recited in claim 1, wherein:
each of the first transistor and the second transistor is a vertical gate all around (GAA) device utilizing a plurality of nanosheets as a channel; and
wherein in response to receiving an indication of a first read operation targeting a row of the plurality of rows comprising the first memory bit cell, the first array is configured to convey data stored in the first memory bit cell.

3. The integrated circuit as recited in claim 2, wherein:
the second active layer comprises a channel configured to conduct current in a direction orthogonal to a direction of current flow in a channel of the first active layer;
the first active layer and the second active layer do not overlap one another; and
a distance between the first active layer and the second active layer is at least a width of a source or drain contact.

4. The integrated circuit as recited in claim 3, wherein:
the first memory bit cell comprises a drain contact contacting an area of a local interconnect layer of the second transistor, between drain nodes of the first transistor and the second transistor; and
the area of the local interconnect layer is not physically adjacent to the second active layer of the second transistor.

5. The integrated circuit as recited in claim 3, wherein the first memory bit cell comprises an asymmetrical layout with respect to placement of transistors and signal nodes within the first memory bit cell.

6. The integrated circuit as recited in claim 3, further comprising a second array of memory bit cells comprising a plurality of rows and a plurality of columns, wherein a highest metal layer used for signal routing in a second memory bit cell of the second array is a metal zero layer.

7. The integrated circuit as recited in claim 6, wherein:
a height of the first memory bit cell is less than a height of the second memory bit cell; and
a width of the first memory bit cell is greater than a width of the second memory bit cell.

8. A method comprising:
forming a first memory bit cell of a first array of memory bit cells, wherein the first memory bit cell comprises a gate contact, between a first gate of a first transistor and a second gate of a second transistor, that overlaps a only one active layer of a first active layer of the first transistor and a second active layer of the second transistor; and
placing, in an integrated circuit, the first array of memory bit cells arranged as a plurality of rows and a plurality of columns.

9. The method as recited in claim 8, further comprising forming the first memory bit cell such that:
each of the first transistor and the second transistor is a vertical gate all around (GAA) device utilizing a plurality of nanosheets as a channel; and
responsive to receiving an indication of a first read operation targeting a row of the plurality of rows comprising the first memory bit cell, conveying, by the first array of memory bit cells, data stored in the first memory bit.

10. The method as recited in claim 9, further comprising forming the first memory bit cell such that:
the second active layer comprises a channel configured to conduct current in a direction orthogonal to a direction of current flow in a channel of the first active layer;
the first active layer and the second active layer do not overlap one another; and
a distance between the first active layer and the second active layer is at least a width of a source or drain contact.

11. The method as recited in claim 10, further comprising forming the first memory bit cell such that:
the first memory bit cell comprises a drain contact contacting an area of a local interconnect layer of the second transistor, between drain nodes of the first transistor and the second transistor; and
the area of the local interconnect layer is not physically adjacent to the second active layer of the second transistor.

12. The method as recited in claim 10, further comprising forming the first memory bit cell such that the first memory bit cell comprises an asymmetrical layout with respect to placement of transistors and signals within the first memory bit cell.

13. The method as recited in claim 10, further comprising forming a second array of memory bit cells comprising a plurality of rows and a plurality of columns, wherein a highest metal layer used for signal routing in a second memory bit cell of the second array is a metal zero layer.

14. The method as recited in claim 13, further comprising forming the second memory bit cell such that:
a height of the first memory bit cell is less than a height of the second memory bit cell; and
a width of the first memory bit cell is greater than a width of the second memory bit cell.

15. A computing system comprising:
an integrated circuit configured to execute instructions using source data, wherein the integrated circuit comprises:
a first array of memory bit cells arranged as a plurality of rows and a plurality of columns;
wherein a first memory bit cell of the first array comprises a gate contact, between a first gate of a first transistor and a second gate of a second transistor, that overlaps only one active layer of a first active layer of the first transistor and a second active layer of the second transistor.

16. The computing system as recited in claim 15, wherein:
each of the first transistor and the second transistor is a vertical gate all around (GAA) device utilizing a plurality of nanosheets as a channel; and
wherein in response to receiving an indication of a first read operation targeting a row of the plurality of rows comprising the first memory bit cell, the first array is configured to convey data stored in the first memory bit cell.

17. The computing system as recited in claim 16, wherein:
the second active layer comprises a channel configured to conduct current in a direction orthogonal to a direction of current flow in a channel of the first active layer;
the first active layer and the second active layer do not overlap one another; and
a distance between the first active layer and the second active layer is at least a width of a source or drain contact.

18. The computing system as recited in claim 17, wherein:
the first memory bit cell comprises, between drain nodes of the first transistor and the second transistor, a drain contact contacting an area of a local interconnect layer of the second transistor; and
the area of the local interconnect layer is not physically adjacent to the second active layer of the second transistor.

19. The computing system as recited in claim 17, wherein the first memory bit cell comprise an asymmetrical layout with respect to placement of transistors and signals within the first memory bit cell.

20. The computing system as recited in claim 17, further comprising a second array of memory bit cells comprising a plurality of rows and a plurality of columns, wherein a highest metal layer used for signal routing in a second memory bit cell of the second array is a metal zero layer.
